(19) United States
(12) Patent Application Publication
(10) Pub. No.: US 2025/0069965 A1
(43) Pub. Date: Feb. 27, 2025

(54) PACKAGE COMPRISING A SUBSTRATE WITH AN EMBEDDED FRAME

(71) Applicant: QUALCOMM Incorporated, San Diego, CA (US)

(72) Inventors: Ryan LANE, San Diego, CA (US); Charles David PAYNTER, Encinitas, CA (US); William STONE, San Diego, CA (US); Ahmer SYED, San Diego, CA (US); Yue LI, San Diego, CA (US); Kuiwon KANG, San Diego, CA (US); Wei WANG, San Diego, CA (US); Durodami LISK, San Diego, CA (US)

(21) Appl. No.: 18/456,295

(22) Filed: Aug. 25, 2023

(51) Int. Cl. H01L 23/13; H01L 23/00

(52) U.S. Cl. CPC H01L 23/13; H01L 24/16; H01L 24/81; H01L 2224/16227; H01L 2224/16238; H01L 2224/81815; H01L 2924/172; H01L 2924/3511

(57) ABSTRACT

A package comprising an integrated device and a substrate coupled to the integrated device through at least a plurality of solder interconnects. The substrate comprises at least one dielectric layer; a frame at least partially located in the at least one dielectric layer; and a plurality of interconnects located at least partially in the at least one dielectric layer. The frame may be an embedded frame.

### FIELD

Various features relate to packages and substrates.

### BACKGROUND

Packages can include a substrate and an integrated device. The substrate may include a plurality of interconnects. A package is subject to many stresses that can cause warpage in the package, the substrate and/or the integrated device, which can cause one or more components of the package to break. There is an ongoing need to provide packages that are more resistant to warpage, while also minimizing the form factor of the package.

### SUMMARY

Various features relate to packages and substrates.

One example provides a package comprising an integrated device; and a substrate coupled to the integrated device through at least a plurality of solder interconnects. The substrate comprises at least one dielectric layer; an embedded frame at least partially located in the at least one dielectric layer; and a plurality of interconnects located at least partially in the at least one dielectric layer.

Another example provides a package that includes an integrated device; a substrate coupled to the integrated device through at least a first plurality of solder interconnects; a second plurality of solder interconnects coupled to a second surface of the substrate; and a frame coupled to the second surface of the substrate. The integrated device is coupled to a first surface of the substrate. The substrate comprises at least one dielectric layer; and a plurality of interconnects located at least partially in the at least one dielectric layer.

Another example provides a substrate. The substrate comprises at least one dielectric layer; an embedded frame at least partially located in the at least one dielectric layer; and a plurality of interconnects located at least partially in the at least one dielectric layer.

Another example provides a substrate. The substrate comprises at least one dielectric layer; a plurality of interconnects located at least partially in the at least one dielectric layer; a plurality of solder interconnects coupled to a surface of the substrate; and a frame coupled to the surface of the substrate.

Another example provides a method for fabricating a package. The method provides a substrate comprising at least one dielectric layer; an embedded frame at least partially located in the at least one dielectric layer; and a plurality of interconnects located at least partially in the at least one dielectric layer. The method couples an integrated device to the substrate through at least a plurality of solder interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary profile view of a package comprising a substrate with an embedded frame.

FIG. 2 illustrates a close up view of an exemplary profile view of a substrate with an embedded frame in a substrate.

FIG. 3 illustrates an exemplary plan view of a frame that may be embedded in a substrate.

FIG. 4 illustrates an exemplary profile view of a package comprising a substrate with an embedded frame.

FIG. 5 illustrates a close up view of an exemplary profile view of a substrate with an embedded frame.

FIG. 6 illustrates an exemplary profile view of a package comprising a substrate with an embedded frame, a first frame coupled to a first surface of the substrate, and a second frame coupled to a second surface of the substrate.

FIG. 7 illustrates an exemplary top plan view of a package comprising a substrate with an embedded frame, a first frame coupled to a first surface of the substrate, and a second frame coupled to a second surface of the substrate.

FIG. 8 illustrates an exemplary bottom plan view of a package comprising a substrate with an embedded frame, a first frame coupled to a first surface of the substrate, and a second frame coupled to a second surface of the substrate.

FIG. 9 illustrates an exemplary profile view of another package comprising a substrate with an embedded frame, a first frame coupled to a first surface of the substrate, and a second frame coupled to a second surface of the substrate.

FIG. 10 illustrates a profile view of an exemplary warpage of a package comprising a substrate without an embedded frame.

FIG. 11 illustrates a profile view of an exemplary warpage of a package comprising a substrate with an embedded frame.

FIG. 12 illustrates an exemplary sequence for fabricating a frame that may be embedded in a substrate.

FIGS. 13A-13E illustrate an exemplary sequence for fabricating a substrate with an embedded frame.

FIG. 14 illustrates an exemplary method of fabricating a substrate with an embedded frame.

FIGS. 15A-15G illustrate an exemplary sequence for fabricating a substrate with an embedded frame.

FIG. 16 illustrates an exemplary method of fabricating a substrate with an embedded frame.

FIG. 17 illustrates an exemplary sequence for fabricating a package comprising a substrate an embedded frame, a first frame coupled to a first surface of the substrate, and a second frame coupled to a second surface of the substrate.

FIG. 18 illustrates an exemplary plan view of another frame that may be embedded in a substrate.

FIG. 19 illustrates an exemplary plan view of another frame that may be embedded in a substrate.

FIG. 20 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device and a substrate coupled to the integrated device. The substrate comprises at least one dielectric layer, an embedded frame at least partially located in the at least one dielectric layer and a plurality of interconnects located at least partially in the at least one dielectric layer. In some implementations, the package may include a first frame coupled to a first surface of the substrate, and a second frame coupled to a second surface of the substrate. The embedded frame, the first frame and/or the second frame are configured as stiffeners for the substrate. The use of the embedded frame, the first frame and/or the second frame helps provide a more robust substrate that is less likely to warp and/or warp to a lesser degree due to various stresses on the package. The use of an embedded frame may help reduce the overall form package, which would allow the package to be implemented in smaller devices.

Exemplary Package with a Substrate Comprising an Embedded Frame

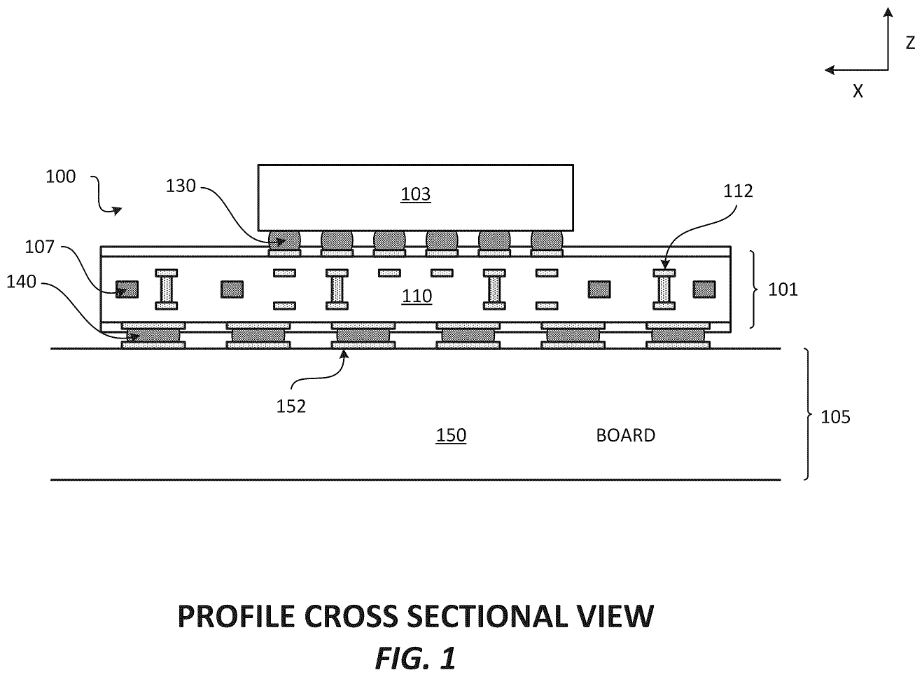

FIG. 1 illustrates an example of a package that includes a substrate that comprises an embedded frame. The embedded frame is configured as a stiffener for the substrate and/or the package. FIG. 1 illustrates a profile view of a package 100 that includes a substrate 101 and an integrated device 103. The package 100 is coupled to a board 105 through at least a plurality of solder interconnects 140. The board 105 includes at least one board dielectric layer 150 and a plurality of board interconnects 152. The plurality of solder interconnects 140 are coupled to the plurality of board interconnects 152 and interconnects from the substrate 101. The substrate 101 may be a coreless substrate. The integrated device 103 may be coupled to the substrate 101 through at least a plurality of bump interconnects 130. A plurality of bump interconnects 130 may include a plurality of pillar interconnects and/or a plurality of solder interconnects.

The substrate 101 may be a package substrate. The substrate 101 includes at least one dielectric layer 110, a plurality of interconnects 112 (e.g., substrate interconnects) and an embedded frame 107. The embedded frame 107 is located in the substrate 101. The embedded frame 107 may be a frame that is partially located (e.g., partially embedded) in the substrate 101 or fully located (e.g., fully embedded) in the substrate 101. The embedded frame 107 is located in the at least one dielectric layer 110. The embedded frame 107 is at least partially surrounded by the at least one dielectric layer 110. The embedded frame 107 may be a frame (e.g., a first frame) that is at least partially located (e.g., partially embedded) in the at least one dielectric layer 110. The embedded frame 107 may include a metal frame. The material and/or composition of the embedded frame 107 may be different from the plurality of interconnects 112. Different implementations may use different materials and/or composition for the embedded frame 107. The embedded frame 107 may include an alloy. The embedded frame 107 may be one contiguous and/or continuous frame. For example, the embedded frame 107 may be a unibody embedded frame. In some implementations, the embedded frame 107 may be defined by several frames and/or several separate frame portions. The substrate 101 may include several embedded frames. Thus, the embedded frame 107 may be part of several frames that are embedded in the substrate 101. In some implementations, the embedded frame 107 may be configured to be free of any electrical connection with an active component (e.g., transistor). In some implementations, the embedded frame 107 may be configured to not be electrically coupled to interconnects of the substrate 101, that are configured to be electrically coupled to active components and/or passive components of the substrate and/or the package.

The embedded frame 107 is configured as a stiffener for the substrate 101 and/or the package 100. The embedded frame 107 may be an embedded lead frame. The embedded frame 107 is made of a material that is stronger than the at least one dielectric layer 110, which helps strengthen the substrate 101 and/or the package 100. This in turns, makes the substrate 101 and/or the package 100 more resistant to stresses and thus, the substrate 101 and/or the package 100 is less likely to warp, or to warp less. In addition, by embedding the frame in the substrate 101, the overall form factor of the substrate 101 and/or the package 100 may be minimized and/or reduced. The embedded frame 107 may occupy space in the substrate 101 that would normally be occupied by a dielectric layer, which may mean that the embedded frame 107 may be implemented in the substrate 101 without increasing the overall size and/or thickness of the substrate 101.

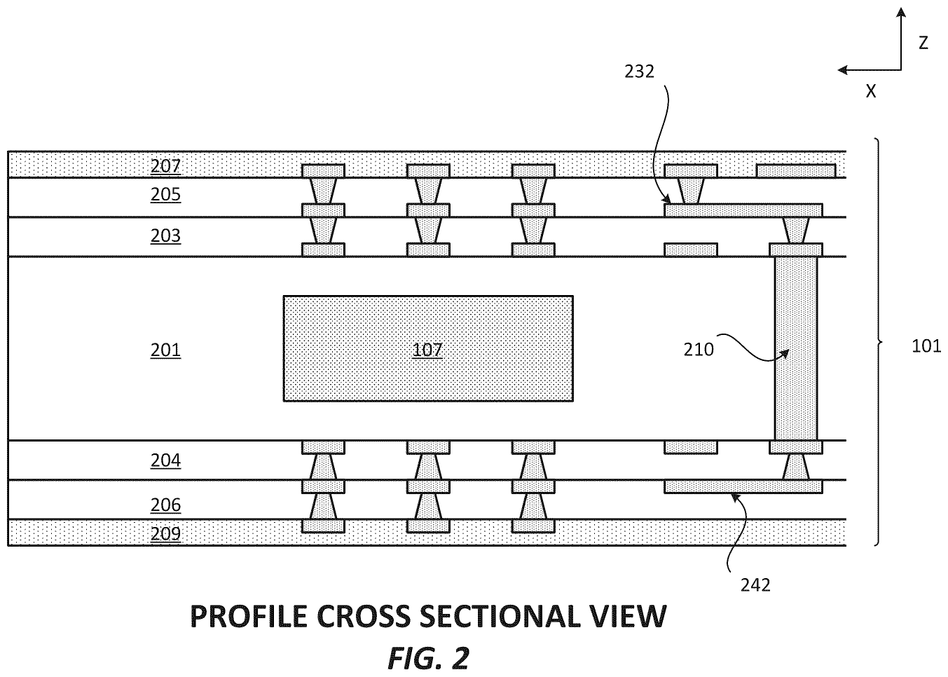

FIG. 2 illustrates a close up view of the substrate 101 that includes an embedded frame 107. As shown in FIG. 2, the substrate 101 includes a dielectric layer 201, a dielectric layer 203, a dielectric layer 204, a dielectric layer 205, a dielectric layer 206, a solder resist layer 207, a solder resist layer 209, a plurality of via interconnects 210, a plurality of interconnects 232 and a plurality of interconnects 242. The dielectric layer 201, the dielectric layer 203, the dielectric layer 204, the dielectric layer 205, and/or the dielectric layer 206 may be represented as the at least one dielectric layer 110 in FIG. 1. The plurality of via interconnects 210 may be located at least partially in the dielectric layer 201. The plurality of interconnects 232 may be located at least partially in the dielectric layer 203 and/or the dielectric layer 205. The plurality of interconnects 242 may be located at least partially in the dielectric layer 204 and/or the dielectric layer 206. The plurality of via interconnects 210 are coupled to the plurality of interconnects 232 and the plurality of interconnects 242. The plurality of via interconnects 210, the plurality of interconnects 232 and/or the plurality of interconnects 242 may be represented as the plurality of interconnects 112 in FIG. 1. The solder resist layer 207 is coupled to a surface of the dielectric layer 205. The solder resist layer 209 is coupled to a surface of the dielectric layer 206.

As shown in FIG. 2, the embedded frame 107 is located in the dielectric layer 201 and is surrounded at least partially by the dielectric layer 201. The dielectric layer 201 may be touching the embedded frame 107. The embedded frame 107 may be located along a periphery of the substrate 101. In some implementations, the embedded frame 107 may be located near and/or about the vertical center of the substrate 101.

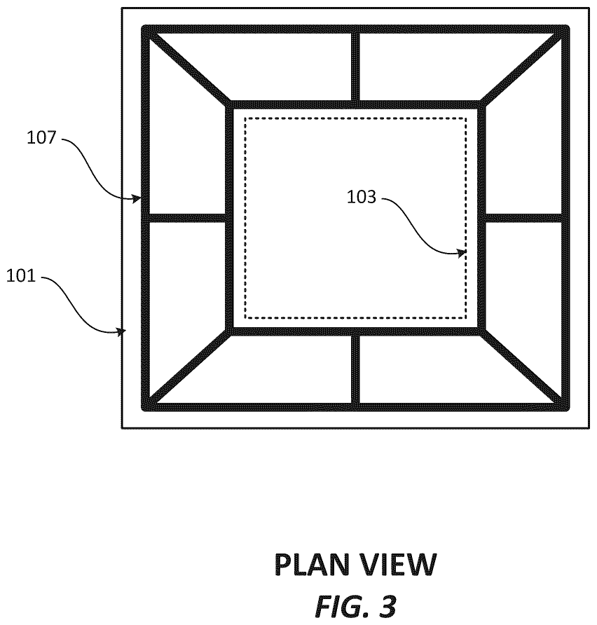

FIG. 3 illustrates a plan view of the substrate 101 with the embedded frame 107. The embedded frame 107 has a design and/or configuration, where portions of the embedded frame 107 extend along a periphery of the substrate 101. Additionally portions of the embedded frame 107 may extend in the substrate 101 along and/or near edges of the of the integrated device 103. Different implementations may have an embedded frame 107 with different designs and/or configurations. The embedded frame 107 may travel in various directions (e.g., straight, diagonal, along length, along width). The embedded frame 107 may be located on different levels of the substrate. The embedded frame 107 does not need to be planar and/or flat. The designs and/or configurations of the embedded frame 107 may be applicable to any type of substrate.

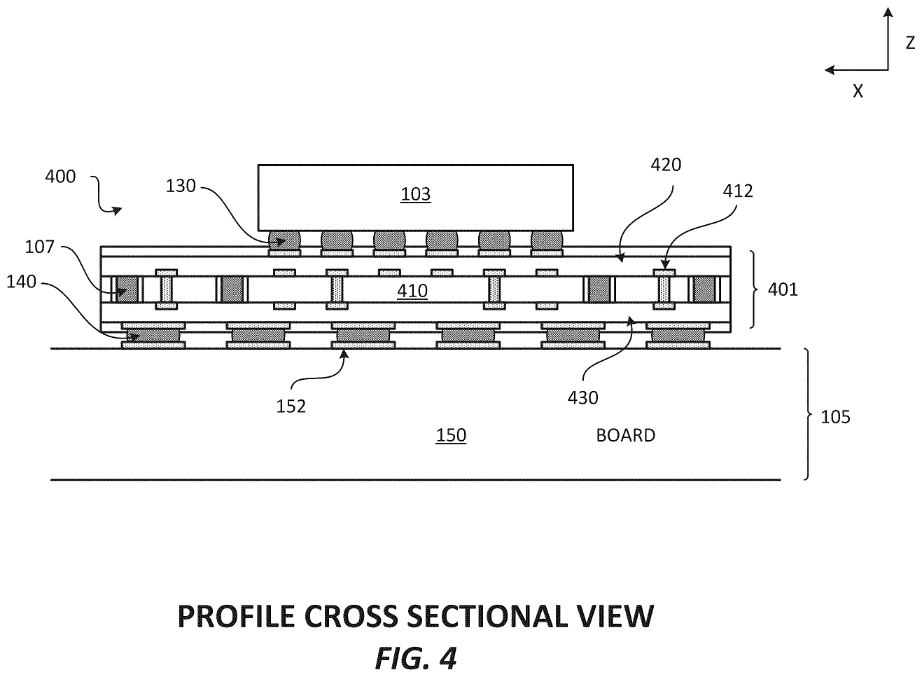

FIG. 4 illustrates an example of another package that includes a substrate that comprises an embedded frame. The embedded frame is configured as a stiffener for the substrate and/or the package. FIG. 4 illustrates a profile view of a package 400 that includes a substrate 401 and an integrated device 103. The package 400 is coupled to the board 105 through at least a plurality of solder interconnects 140. The plurality of solder interconnects 140 are coupled to the plurality of board interconnects 152 and interconnects from the substrate 101. The substrate 401 is similar to the substrate 101. However, the substrate 401 includes a core layer. The substrate 401 may be a cored substrate. The integrated device 103 may be coupled to the substrate 401 through at least a plurality of bump interconnects 130. A plurality of bump interconnects 130 may include a plurality of pillar interconnects and/or a plurality of solder interconnects.

The substrate 401 may be a package substrate. The substrate 401 includes a core layer 410, at least one dielectric layer 420, at least one dielectric layer 430, a plurality of interconnects 412 (e.g., substrate interconnects) and an embedded frame 107. The embedded frame 107 is located in the substrate 401. The embedded frame 107 may be located in the core layer 410, the at least one dielectric layer 420 and/or the at least one dielectric layer 430. The embedded frame 107 may be at least partially surrounded by the core layer 410. However, the embedded frame 107 may be touched by the at least one dielectric layer 420 and/or the at least one dielectric layer 430. The at least one dielectric layer 420 may be coupled to a first surface of the core layer 410. The at least one dielectric layer 430 may be coupled to a second surface of the core layer 410. The embedded frame 107 may include a metal frame. The material and/or composition of the embedded frame 107 may be different from the plurality of interconnects 412. Different implementations may use different materials and/or composition for the embedded frame 107. The embedded frame 107 may be one contiguous and/or continuous frame. For example, the embedded frame 107 may be a unibody embedded frame. In some implementations, the embedded frame 107 may be defined by several frames. The substrate 401 may include several embedded frames. Thus, the embedded frame 107 may be part of several frames that are embedded in the substrate 401. In some implementations, the embedded frame 107 may be configured to be free of any electrical connection with an active component (e.g., transistor). In some implementations, the embedded frame 107 may be configured to not be electrically coupled to interconnects (e.g., interconnects that are configured to provide an electrical path for power and/or signals) of the substrate 401. The same benefits of the embedded frame 107 for the substrate 101, as described above may be applicable to the substrate 401. In some implementations, the embedded frame 107 may be touching an interconnect that is not configured to provide an electrical path for power and/or signals.

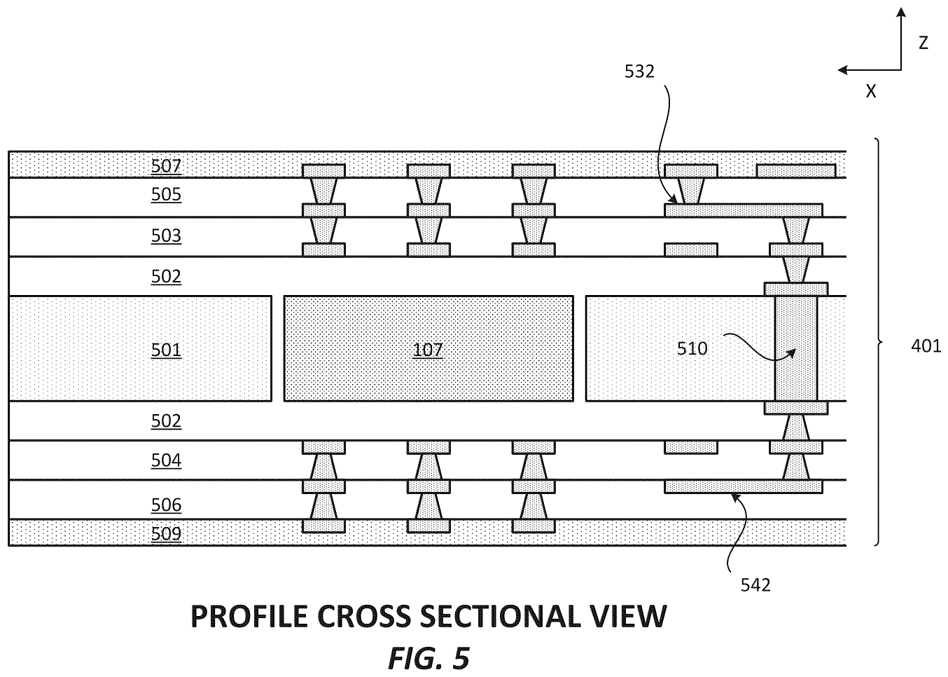

FIG. 5 illustrates a close up view of the substrate 401 that includes an embedded frame 107. As shown in FIG. 5, the substrate 401 includes a core layer 501, a dielectric layer 502, a dielectric layer 503, a dielectric layer 504, a dielectric layer 505, a dielectric layer 506, a solder resist layer 507, a solder resist layer 509, a plurality of via interconnects 510, a plurality of interconnects 532 and a plurality of interconnects 542. The core layer 501 may represent the core layer 410 of FIG. 4. The dielectric layer 502, the dielectric layer 503, the dielectric layer 504, the dielectric layer 505, and/or the dielectric layer 506 may be represented as the at least one dielectric layer 420 and/or the at least one dielectric layer 430 in FIG. 4. The plurality of via interconnects 510 may be located at least partially in the core layer 501. The plurality of interconnects 532 may be located at least partially in the dielectric layer 502, the dielectric layer 503 and/or the dielectric layer 505. The plurality of interconnects 542 may be located at least partially in the dielectric layer 502, the dielectric layer 504 and/or the dielectric layer 506. The plurality of via interconnects 510 are coupled to the plurality of interconnects 532 and the plurality of interconnects 542. The plurality of via interconnects 510, the plurality of interconnects 532 and/or the plurality of interconnects 542 may be represented as the plurality of interconnects 412 in FIG. 4. The solder resist layer 507 is coupled to a surface of the dielectric layer 505. The solder resist layer 509 is coupled to a surface of the dielectric layer 506.

As shown in FIG. 5, the embedded frame 107 is located in the dielectric layer 502 and is surrounded at least partially by the dielectric layer 502. The dielectric layer 502 may be touching the embedded frame 107. The embedded frame 107 may be considered to be located in a cavity of the core layer 501 and may be at least partially surrounded by the core layer 501. Portions of the dielectric layer 502 may be located in the cavity of the core layer 501. The embedded frame 107 may be located along a periphery of the substrate 401. In some implementations, the embedded frame 107 may be located near and/or about the vertical center of the substrate 401.

In some implementations, additional frames and/or stiffeners may be implemented, and/or implemented as a standalone frame.

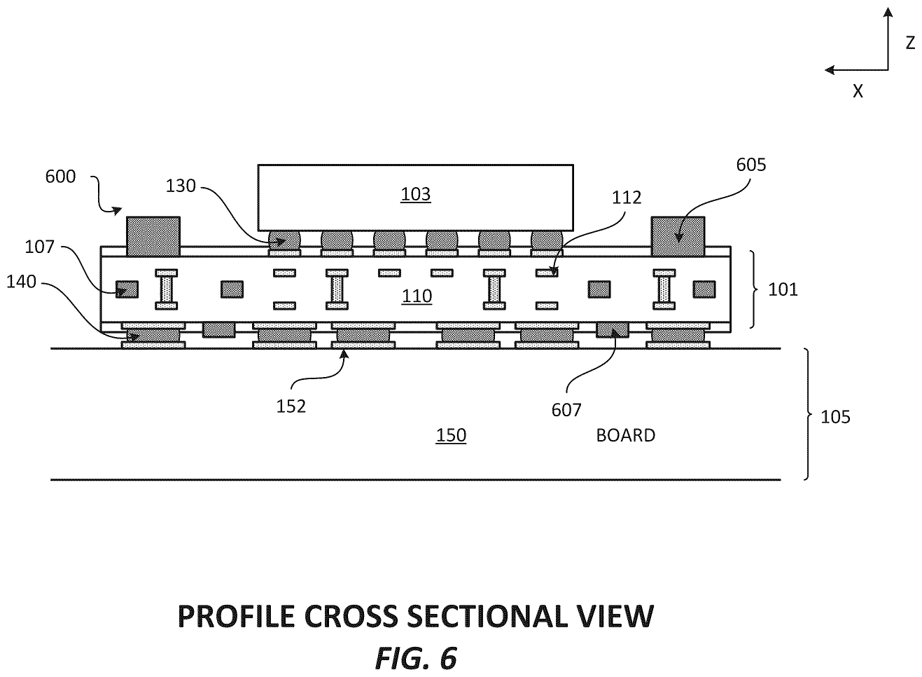

FIG. 6 illustrates an example of a package that includes a substrate that comprises an embedded frame and other frames. FIG. 6 illustrates a profile view of a package 600 that includes a substrate 101 and an integrated device 103. The package 600 is coupled to a board 105 through at least a plurality of solder interconnects 140. The substrate 101 includes the embedded frame 107 as described in FIG. 1. The package 600 is similar to the package 100. However, the package 600 includes additional frames and/or stiffeners. The additional frames may help further strengthen the substrate and/or the package.

As shown in FIG. 6, the package 600 includes a frame 605 and a frame 607. The frame 605 and/or the frame 607 may be stiffeners. The frame 607 may be a first frame. The frame 607 is coupled to a bottom surface of the substrate 101. The frame 607 may be considered to be coupled to the landside surface of the substrate 101. An adhesive and/or solder may be used to couple the frame 607 to the substrate 101. The frame 607 may be coupled to the at least one dielectric layer 110 and/or a solder resist layer of the substrate 101. In some implementations, the frame 607 may be coupled to interconnects of the substrate 101. The frame 607 may be made of a similar material and/or composition as the embedded frame 107. However, different implementations may use different materials and/or composition for the frame 607. The frame 607 may be have ring pattern (e.g., square ring pattern). The frame 607 may be laterally surrounded by the plurality of solder interconnects 140. The frame 607 may be a lead frame.

FIG. 6 also illustrates the frame 605 that is coupled to a top side of the substrate 101. The frame 605 may be a second frame. However, in some implementations, the frame 605 may be a first frame and the frame 607 may be a second frame. The frame 605 is coupled to a top surface of the substrate 101. The frame 605 may be considered to be coupled to the die side surface of the substrate 101. An adhesive and/or solder may be used to couple the frame 605 to the substrate 101. The frame 605 may be coupled to at least one dielectric layer 110 and/or a solder resist layer of the substrate 101. In some implementations, the frame 605 may be coupled to interconnects of the substrate 101. The frame 605 may be made of a similar material and/or composition as the embedded frame 107. However, different implementations may use different materials and/or composition for the frame 605. The frame 605 may be a lead frame. In some implementations, the frame 605 and/or the frame 607 may be configured to be free of any electrical connection with an active component (e.g., transistor). In some implementations, the frame 605 and/or the frame 607 may be configured to not be electrically coupled to interconnects (e.g., interconnects that are configured to provide an electrical path for power and/or signals) of the substrate 101. In some implementations, the frame 605 and/or the frame 607 may be touching an interconnect that is not configured to provide an electrical path for power and/or signals.

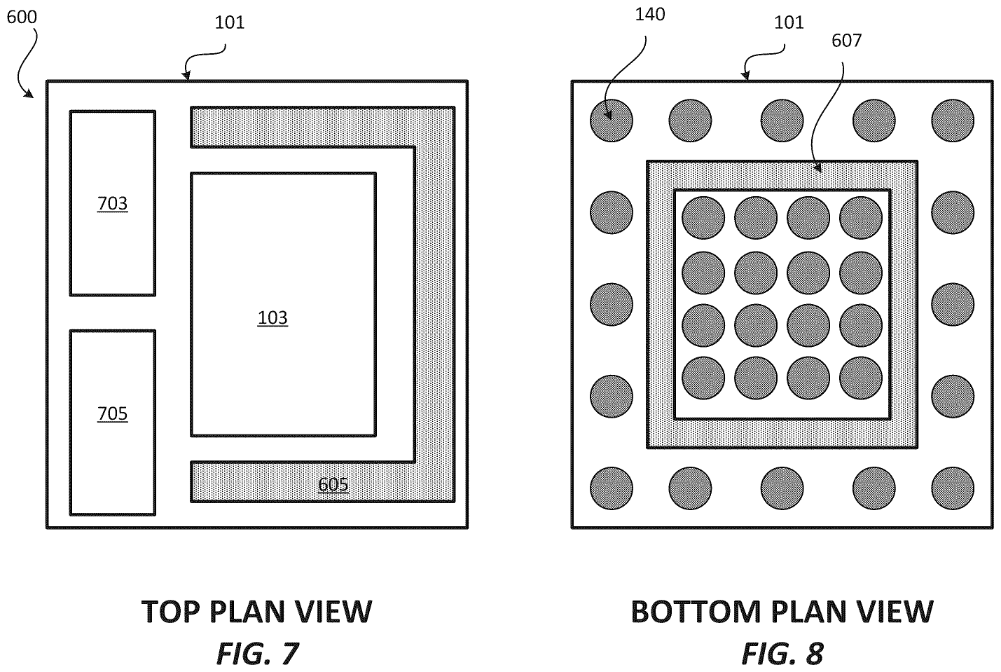

FIG. 7 illustrates a top plan view (e.g., die side plan view) of the package 600. As shown in FIG. 7, an integrated device 703 and an integrated device 705 are coupled to the substrate 101. The integrated device 103 is partially and laterally surrounded by the frame 605. The frame 605 may be partially located along a periphery of the substrate 101, and may follow part of the contour of the periphery of the substrate 101.

FIG. 8 illustrates a bottom plan view (e.g., landside plan view) of the package 600. As shown in FIG. 8, the frame 607 is laterally surrounded by some solder interconnects from the plurality of solder interconnects 140. Moreover, the frame 607 laterally surrounds some solder interconnects from the plurality of solder interconnects 140. In some implementations, the frame 607 may laterally surround all of the solder interconnects from the plurality of solder interconnects 140.

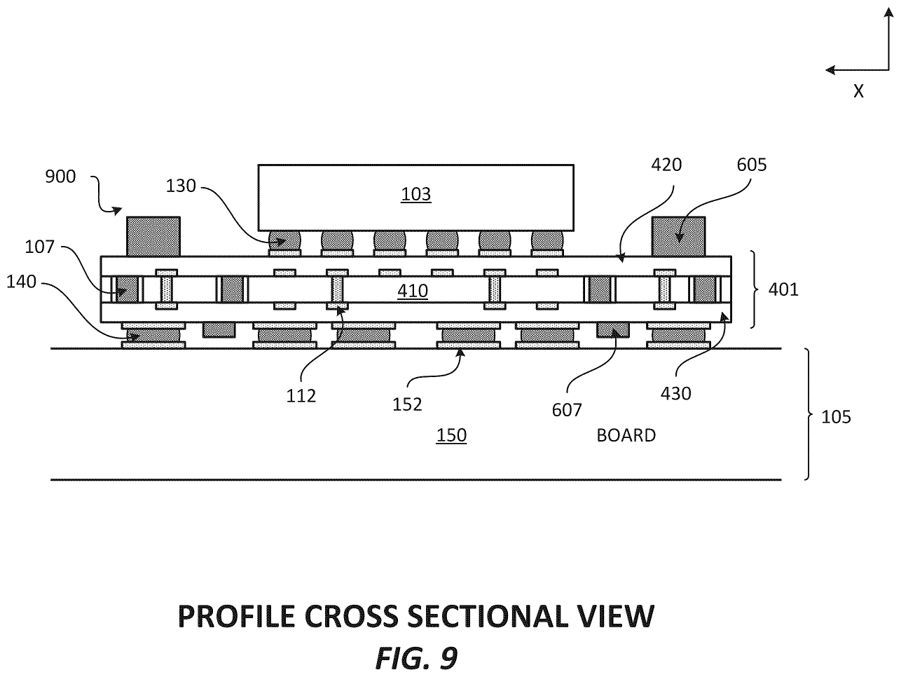

FIG. 9 illustrates an example of another package that includes a substrate that comprises an embedded frame and other frames. FIG. 9 illustrates a profile view of a package 900 that includes a substrate 401 and an integrated device 103. The package 900 is coupled to a board 105 through at least a plurality of solder interconnects 140. The substrate 401 includes the embedded frame 107 as described in FIG. 4. The package 900 is similar to the package 400. However, the package 900 includes additional frames and/or stiffeners. The package 900 is similar to the package 600. However, the package 900 includes a substrate with a core layer.

As shown in FIG. 9, the package 900 includes a frame 605 and a frame 607. The frame 605 and/or the frame 607 may be stiffeners. The frame 607 may be a first frame. The frame 607 is coupled to a bottom surface of the substrate 101. The frame 607 may be considered to be coupled to the landside surface of the substrate 401. An adhesive and/or solder may be used to couple the frame 607 to the substrate 401. The frame 607 may be coupled to the at least one dielectric layer 430 and/or a solder resist layer of the substrate 401. In some implementations, the frame 607 may be coupled to interconnects of the substrate 401. The frame 607 may be made of a similar material and/or composition as the embedded frame 107. However, different implementations may use different materials and/or composition for the frame 607. The frame 607 may be have ring pattern (e.g., square ring pattern). The frame 607 may be laterally surrounded by the plurality of solder interconnects 140.

FIG. 9 also illustrates the frame 605 that is coupled to a top side of the substrate 401. The frame 605 may be a second frame. However, in some implementations, the frame 605 may be a first frame and the frame 607 may be a second frame. The frame 605 is coupled to a top surface of the substrate 401. The frame 605 may be considered to be coupled to the die side surface of the substrate 401. An adhesive and/or solder may be used to couple the frame 605 to the substrate 401. The frame 605 may be coupled to the at least one dielectric layer 420 and/or a solder resist layer of the substrate 401. In some implementations, the frame 605 may be coupled to interconnects of the substrate 401.

In some implementations, the frame 605 and/or the frame 607 may be configured to be free of any electrical connection with an active component (e.g., transistor). In some implementations, the frame 605 and/or the frame 607 may be configured to not be electrically coupled to interconnects (e.g., interconnects that are configured to provide an electrical path for power and/or signals) of the substrate 101. In some implementations, the frame 605 and/or the frame 607 may be touching an interconnect that is not configured to provide an electrical path for power and/or signals.

The frame 605 and/or the frame 607 may be made of a similar material and/or composition as the embedded frame 107. However, different implementations may use different materials and/or composition for the frame 605 and/or the frame 607.

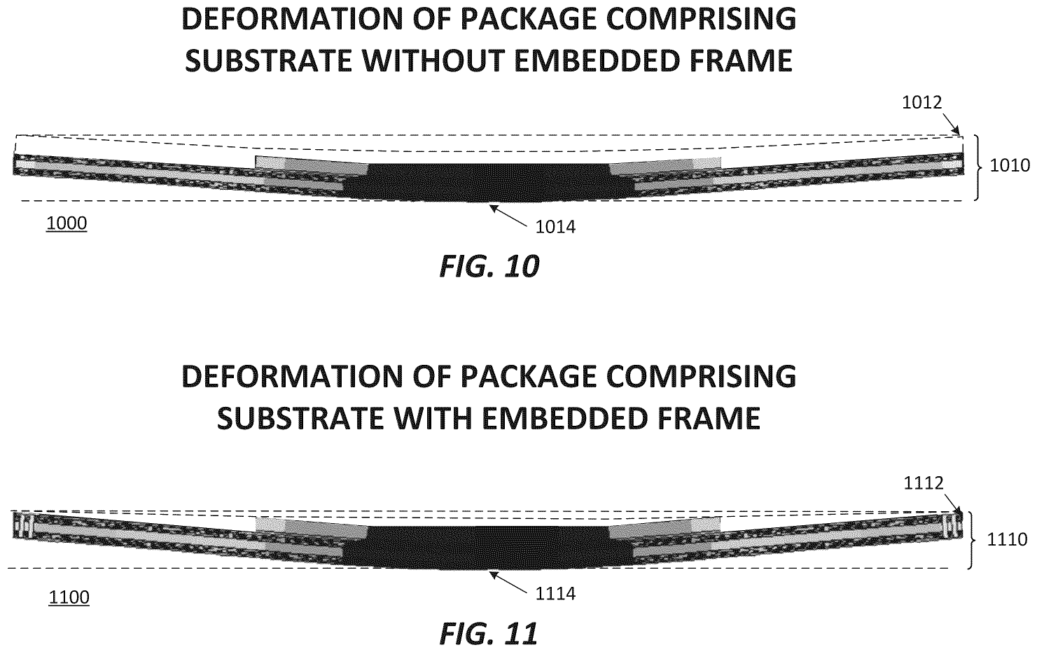

As mentioned above, the embedded frame 107 helps stiffen the substrate and/or the package, which helps reduce and/or minimize warpage that may occur in the substrate and/or the package. FIG. 10 illustrates an example of warpage that may occur in a package that includes (i) an integrated device and (ii) a substrate without an embedded frame. The displacement 1010 illustrates the total displacement of the substrate from warpage. The displacement 1010 may be the difference between a high point 1012 of the substrate and a low point 1014 of the substrate. In one example, the low point 1014 of the substrate may be a center bottom portion of the substrate. In one example, the high point 1012 of the substrate may be a top edge portion of the substrate. The high point 1012 of the substrate is located on a different cross section of the substrate than what is shown in FIG. 10, which is why it is not visible in FIG. 10. FIG. 11 illustrates an example of warpage that may occur in a package that includes (i) an integrated device and (ii) a substrate with an embedded frame. The displacement 1110 illustrates the total displacement of the substrate from warpage. The displacement 1110 may be a difference between a high point 1112 of the substrate and a low point 1114 of the substrate. In one example, the low point 1114 of the substrate may be a center bottom portion of the substrate. In one example, the high point 1112 of the substrate may be a top edge portion of the substrate. FIGS. 10 and 11 illustrate that there is much more warpage, displacement and/or vertical deflection in the package and substrate without the embedded frame. For example, the displacement 1010 is greater than the displacement 1110. It should be noted that the warpage and/or vertical deflections shown in FIGS. 10 and 11 are exemplary. Different implementations may have different warpage, displacement and/or vertical deflection based on the design and/or configuration of the embedded frame. As mentioned above, one benefit of the embedded frame in the substrate is that the size and/or thickness of the substrate may not need to be increased in order to accommodate the embedded frame. Thus, the embedded frame provides a very effective way of strengthening the substrate and/or the package, while maintaining, minimizing and/or reducing the size of the substrate and/or the package.

An integrated device may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc.,). An integrated device may include transistors. An integrated device may be an example of an electrical component and/or electrical device. In some implementations, an integrated device may include a chiplet. A chiplet may be fabricated using a process that provides better yields compared to other processes that are used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

### Exemplary Fabrication of an Embedded Frame

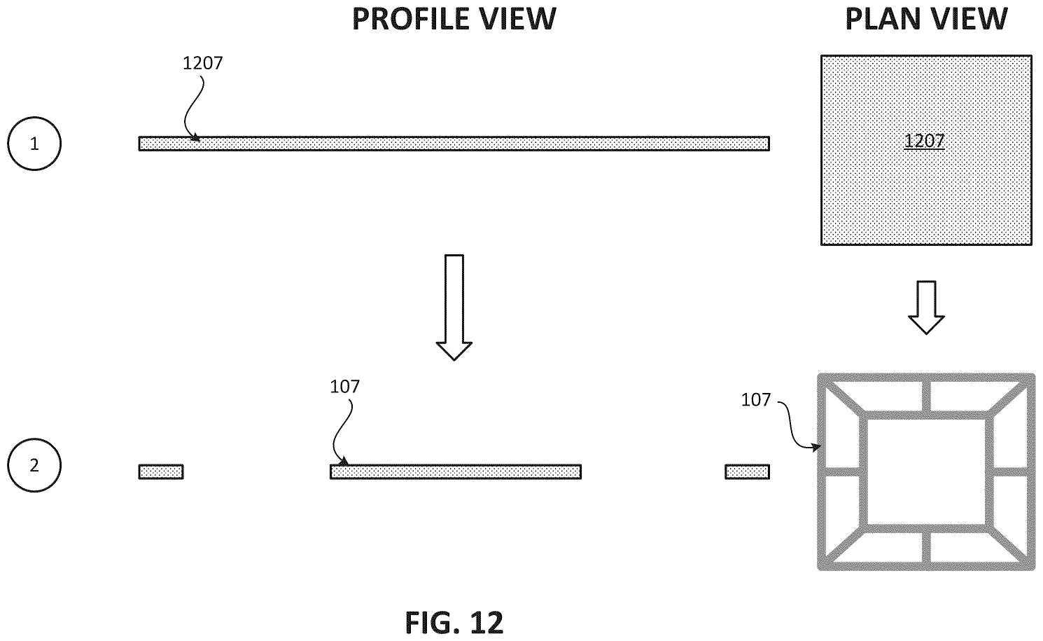

Different implementations may use different materials, different compositions and/or different designs for an embedded frame. FIG. 12 conceptually illustrates how a frame may be fabricated to be embedded in a substrate. Different implementations may fabricate a frame differently.

Stage 1 of FIG. 12 illustrates a state after a sheet 1207 is provided. The sheet 1207 may be a metal sheet. Different implementations may use different materials for the sheet 1207. The sheet 1207 may include an alloy.

Stage 2 illustrates a state after a design of the embedded frame 107 is formed from the sheet 1207. A stamping process may be used to form the embedded frame 107 from the sheet 1207. In some implementations, a laser may be used to cut the design of the embedded frame 107.

Exemplary Sequence for Fabricating a Substrate with an Embedded Frame

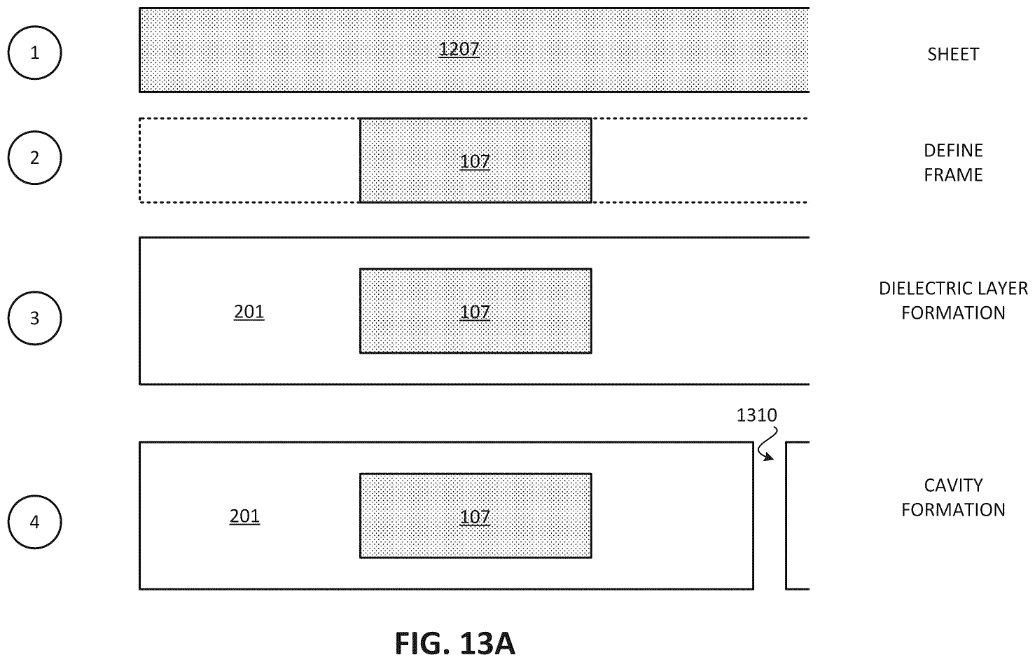

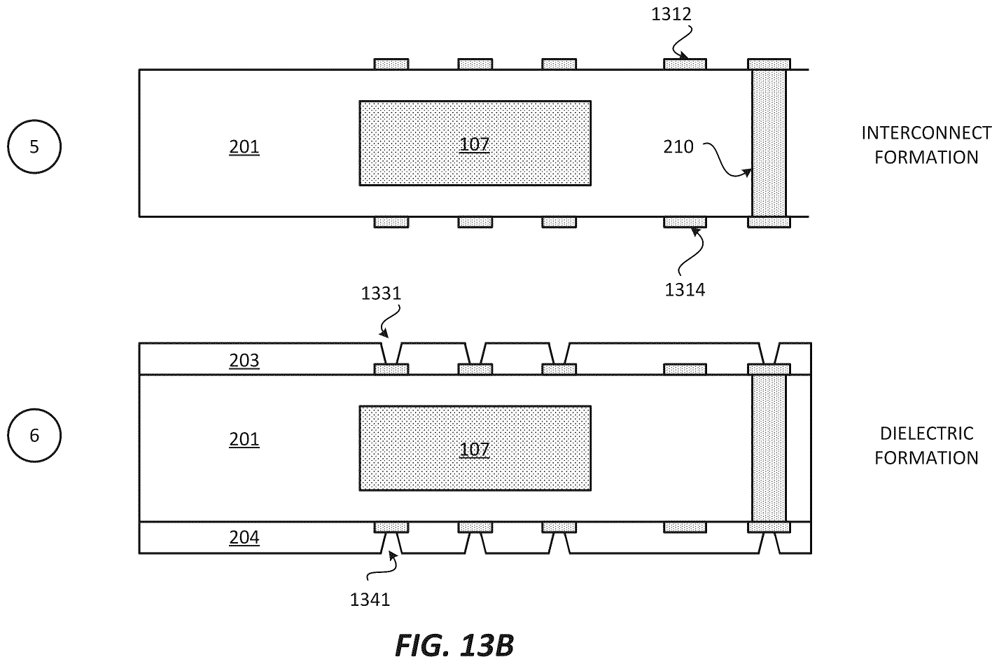

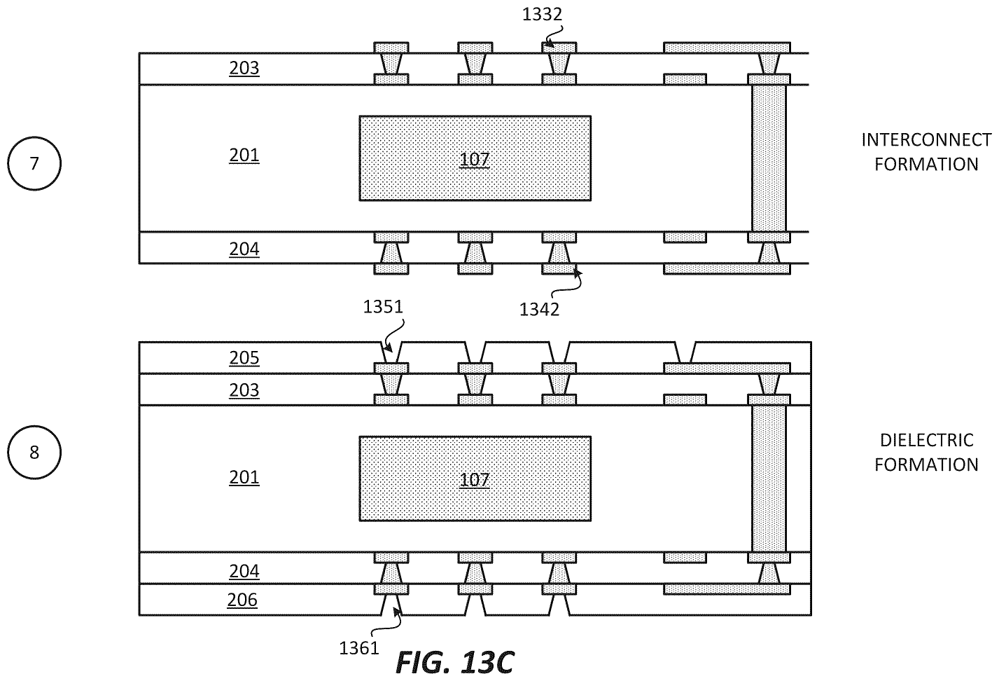

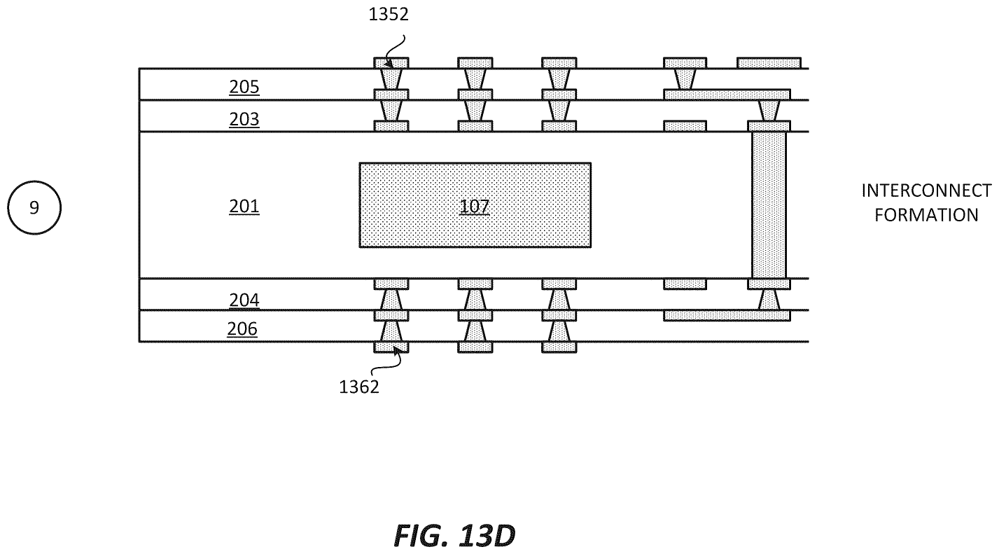

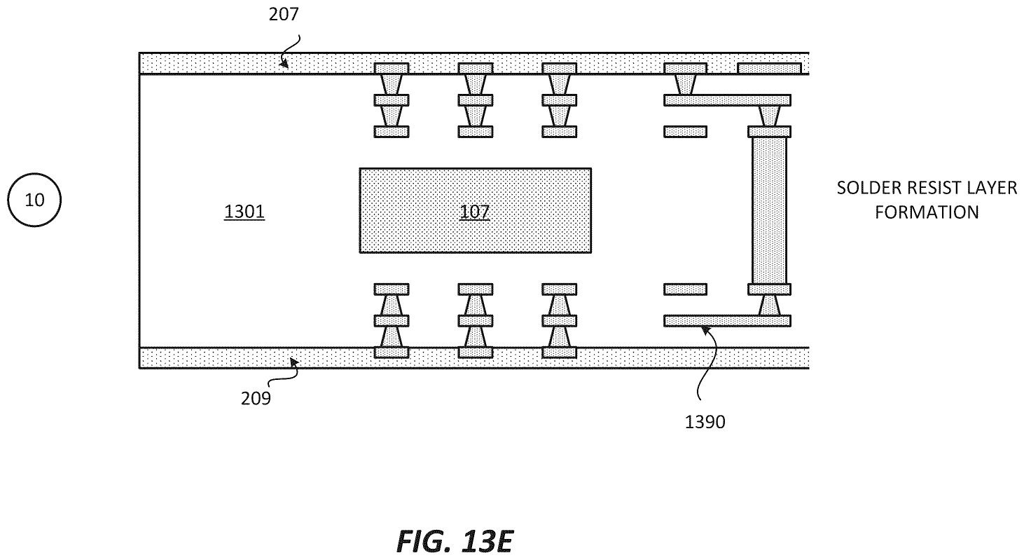

FIGS. 13A-13E illustrate an exemplary sequence for providing or fabricating a substrate with an embedded frame. In some implementations, the sequence of FIGS. 13A-13E may be used to provide or fabricate any of the substrates described in the disclosure. In some implementations, the sequence of FIGS. 13A-13E may be used to provide or fabricate the substrate 101 described in the disclosure.

It should be noted that the sequence of FIGS. 13A-13E may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 13A, illustrates a state after a sheet 1207 is provided. The sheet 1207 may be a metal sheet. The sheet 1207 may include an alloy.

Stage 2 illustrates a state after the sheet 1207 is cut and/or defined to form the design of the embedded frame 107. In some implementations, a stamping process may be used to define the embedded frame 107.

Stage 3 illustrates a state after a dielectric layer 201 is formed around the embedded frame 107. The dielectric layer 201 touches the embedded frame 107. The dielectric layer 201 at least partially surrounds the embedded frame 107. A deposition process and/or a lamination process may be used to form the dielectric layer 201. The dielectric layer 201 may represent one or more dielectric layers.

Stage 4 illustrates a state after a plurality of cavities 1310 are formed in the dielectric layer 201. The plurality of cavities 1310 may extend through the dielectric layer 201. A laser process (e.g., laser ablation) may be used to form the plurality of cavities 1310. However, different implementations may use different processes to form the plurality of cavities 1310.

Stage 5, as shown in FIG. 13B illustrates a state after a plurality of via interconnects 210, a plurality of interconnects 1312 and a plurality of interconnects 1314 are formed. The plurality of via interconnects 210 may be formed in the plurality of cavities 1310. The plurality of interconnects 1312 may be formed and coupled to a first surface of the dielectric layer 201. The plurality of interconnects 1312 may be coupled to the plurality of via interconnects 210. The plurality of interconnects 1314 may be formed and coupled to a second surface of the dielectric layer 201. The plurality of interconnects 1314 may be coupled to the plurality of via interconnects 210. A plating process and a patterning process may be used to form the plurality of via interconnects 210, the plurality of interconnects 1312 and/or the plurality of interconnects 1314.

Stage 6 illustrates a state after a dielectric layer 203 and the dielectric layer 204 are formed. The dielectric layer 203 may include a plurality of cavities 1331. The dielectric layer 204 may include a plurality of cavities 1341. The dielectric layer 203 may be formed and coupled to a first surface (e.g., top surface) of the dielectric layer 201. The dielectric layer 204 may be formed and coupled to a second surface (e.g., bottom surface) of the dielectric layer 201. In some implementations, the dielectric layer 203 and/or the dielectric layer 204 may include a polymer. In some implementations, the dielectric layer 203 and/or the dielectric layer 204 may include Ajinomoto Build-up Film (ABF). In some implementations, the dielectric layer 203 and/or the dielectric layer 204 may include prepreg. The dielectric layer 203 and/or the dielectric layer 204 may be the same or different from the dielectric layer 201.

The plurality of cavities 1331 are formed through a surface (e.g., first surface, top surface) of the dielectric layer 203. A laser process (e.g., laser ablation process) may be used to form the plurality of cavities 1331 in the dielectric layer 203. However, different implementations may use different processes to form the plurality of cavities 1331. The plurality of cavities 1341 are formed through a surface (e.g., second surface, bottom surface) of the dielectric layer 204. A laser process (e.g., laser ablation process) may be used to form the plurality of cavities 1341 in the dielectric layer 204. However, different implementations may use different processes to form the plurality of cavities 1341.

Stage 7, as shown in FIG. 13C, illustrates a plurality of interconnects 1332 that are formed in at least the dielectric layer 203. The plurality of interconnects 1332 are coupled to the plurality of interconnects 1312. Stage 7 also illustrates and describes a plurality of interconnects 1342 that are formed in at least the dielectric layer 204. The plurality of interconnects 1342 are coupled to the plurality of interconnects 1314. A plating process and a patterning process may be used to form the plurality of interconnects 1332 and/or the plurality of interconnects 1342.

Stage 8 illustrates a state after a dielectric layer 205 and the dielectric layer 206 are formed. The dielectric layer 205 may include a plurality of cavities 1351. The dielectric layer 206 may include a plurality of cavities 1361. The dielectric layer 205 may be formed and coupled to a first surface (e.g., top surface) of the dielectric layer 203. The dielectric layer 206 may be formed and coupled to a second surface (e.g., bottom surface) of the dielectric layer 204. In some implementations, the dielectric layer 205 and/or the dielectric layer 206 may include a polymer. In some implementations, the dielectric layer 205 and/or the dielectric layer 206 may include Ajinomoto Build-up Film (ABF). In some implementations, the dielectric layer 205 and/or the dielectric layer 206 may include prepreg. The dielectric layer 205 and/or the dielectric layer 206 may be the same or different from the dielectric layer 203 and/or the dielectric layer 204.

The plurality of cavities 1351 are formed through a surface (e.g., first surface, top surface) of the dielectric layer 205. A laser process (e.g., laser ablation process) may be used to form the plurality of cavities 1351 in the dielectric layer 205. However, different implementations may use different processes to form the plurality of cavities 1351. The plurality of cavities 1361 are formed through a surface (e.g., second surface, bottom surface) of the dielectric layer 206. A laser process (e.g., laser ablation process) may be used to form the plurality of cavities 1361 in the dielectric layer 206. However, different implementations may use different processes to form the plurality of cavities 1361.

Stage 9, as shown in FIG. 13D, illustrates a plurality of interconnects 1352 that are formed in at least the dielectric layer 205. The plurality of interconnects 1352 are coupled to the plurality of interconnects 1332. Stage 9 also illustrates and describes a plurality of interconnects 1362 that are formed in at least the dielectric layer 206. The plurality of interconnects 1362 are coupled to the plurality of interconnects 1342. A plating process and a patterning process may be used to form the plurality of interconnects 1352 and/or the plurality of interconnects 1362.

Stage 10, as shown in FIG. 13E, illustrates a state after a solder resist layer 207 is formed and patterned. The solder resist layer 207 may be coupled to the dielectric layer 1301. The dielectric layer 1301 may be at least one dielectric layer that represents all and/or part of, the dielectric layer 201, the dielectric layer 203, the dielectric layer 205 and/or the dielectric layer 206. A deposition, a lamination, an exposure, a development and/or an etching process may be used to form and pattern the solder resist layer 207. The plurality of interconnects 1390 may be located at least in the dielectric layer 1301. The plurality of interconnects 1390 may represent all and/or part of the plurality of via interconnects 210, the plurality of interconnects 1312, the plurality of interconnects 1314, the plurality of interconnects 1332, the plurality of interconnects 1342, the plurality of interconnects 1352 and/or the plurality of interconnects 1362. The dielectric layer 1301 may represent the at least one dielectric layer 110, as shown in at least FIG. 1. The plurality of interconnects 1390 may represent the plurality of interconnects 112, as shown in FIG. 1.

Stage 10 also illustrates and describes a state after a solder resist layer 209 is formed and patterned. The solder resist layer 209 may be coupled to the dielectric layer 1301. A deposition, a lamination, an exposure, a development and/or an etching process may be used to form and pattern the solder resist layer 209.

Exemplary Flow Diagram of a Method for Fabricating a Substrate with an Embedded Frame

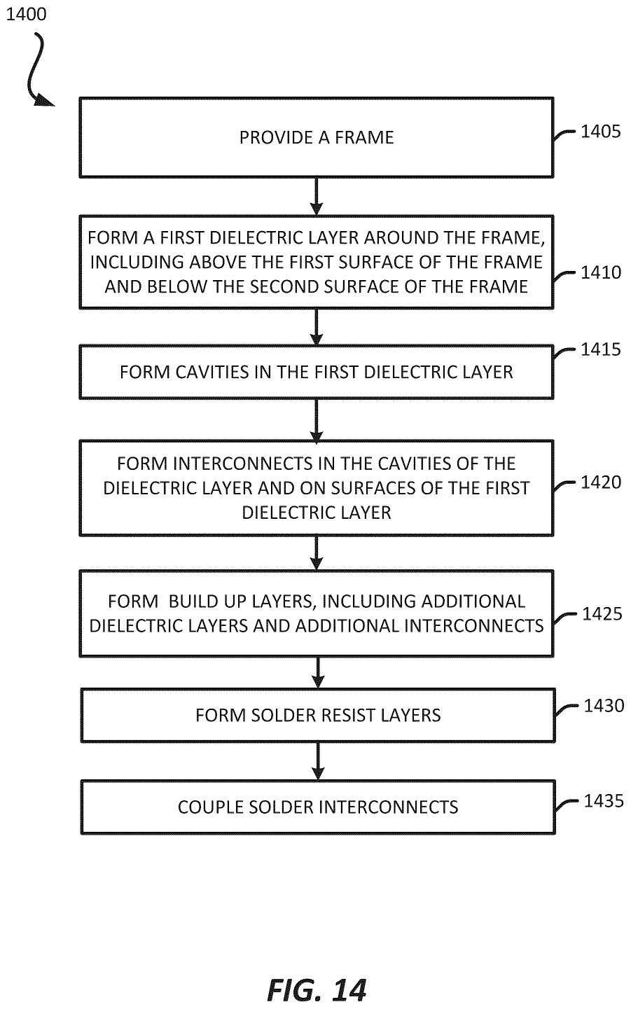

In some implementations, fabricating a substrate includes several processes. FIG. 14 illustrates an exemplary flow diagram of a method 1400 for providing or fabricating a substrate with an embedded frame. In some implementations, the method 1400 of FIG. 14 may be used to provide or fabricate the substrate 101.

It should be noted that the method 1400 of FIG. 14 may combine one or more processes in order to simplify and/or clarify the method for providing or fabricating a substrate. In some implementations, the order of the processes may be changed or modified.

The method provides (at 1405) a frame. The frame may be formed from a sheet that has been cut and/or defined. Stage 1 of FIG. 13A, illustrates and describes an example of a state after a sheet 1207 is provided. The sheet 1207 may be a metal sheet. Stage 2 of FIG. 13A, illustrates and describes an example of a state after the sheet 1207 is cut and/or defined to form the design of the embedded frame 107. A stamping process may be used to define the embedded frame 107.

The method forms (at 1410) a first dielectric layer around the frame, including above a first surface of the first dielectric layer, below a second surface of the first dielectric layer and/or around the lateral surface(s) of the frame. Stage 3 of FIG. 13A, illustrates and describes an example of a state after a dielectric layer 201 is formed. The dielectric layer 201 touches the embedded frame 107. The dielectric layer 201 at least partially surrounds the embedded frame 107. A deposition process and/or a lamination process may be used to form the dielectric layer 201. The dielectric layer 201 may represent one or more dielectric layers.

The method forms (at 1415) a plurality of cavities in the first dielectric layer. Stage 4 of FIG. 13A, illustrates and describes an example of a state after a plurality of cavities 1310 are formed in the dielectric layer 201. The plurality of cavities 1310 may extend through the dielectric layer 201. A laser process (e.g., laser ablation) may be used to form the plurality of cavities 1310. However, different implementations may use different processes to form the plurality of cavities 1310.

The method forms (at 1420) a plurality of via interconnects in the plurality of cavities of the first dielectric layer and a plurality of interconnects on surfaces of the first dielectric layer. Stage 5 of FIG. 13B, illustrates and describes an example of a state after a plurality of via interconnects 210, a plurality of interconnects 1312 and a plurality of interconnects 1314 are formed. The plurality of via interconnects 210 may be formed in the plurality of cavities 1310. The plurality of interconnects 1312 may be formed and coupled to a first surface of the dielectric layer 201. The plurality of interconnects 1312 may be coupled to the plurality of via interconnects 210. The plurality of interconnects 1314 may be formed and coupled to a second surface of the dielectric layer 201. The plurality of interconnects 1314 may be coupled to the plurality of via interconnects 210. A plating process and a patterning process may be used to form the plurality of via interconnects 210, the plurality of interconnects 1312 and/or the plurality of interconnects 1314.

The method forms (at 1425) several build up layers that include at least on dielectric layer and a plurality of interconnects. Stage 6 of FIG. 13B through Stage 9 of FIG. 13D illustrate and describes an example of a state after build layers are formed. Stage 6 of FIG. 13B, illustrates and describes an example of a state after a dielectric layer 203 and the dielectric layer 204 are formed. The dielectric layer 203 may include a plurality of cavities 1331. The dielectric layer 204 may include a plurality of cavities 1341. The dielectric layer 203 may be formed and coupled to a first surface (e.g., top surface) of the dielectric layer 201. The dielectric layer 204 may be formed and coupled to a second surface (e.g., bottom surface) of the dielectric layer 201. In some implementations, the dielectric layer 203 and/or the dielectric layer 204 may include a polymer. In some implementations, the dielectric layer 203 and/or the dielectric layer 204 may include Ajinomoto Build-up Film (ABF). In some implementations, the dielectric layer 203 and/or the dielectric layer 204 may include prepreg. The dielectric layer 203 and/or the dielectric layer 204 may be the same or different from the dielectric layer 201.

The plurality of cavities 1331 are formed through a surface (e.g., first surface, top surface) of the dielectric layer 203. A laser process (e.g., laser ablation process) may be used to form the plurality of cavities 1331 in the dielectric layer 203. However, different implementations may use different processes to form the plurality of cavities 1331. The plurality of cavities 1341 are formed through a surface (e.g., second surface, bottom surface) of the dielectric layer 204. A laser process (e.g., laser ablation process) may be used to form the plurality of cavities 1341 in the dielectric layer 204. However, different implementations may use different processes to form the plurality of cavities 1341.

Stage 7 of FIG. 13C, illustrates and describes an example of a state after a plurality of interconnects 1332 that are formed in at least the dielectric layer 203. The plurality of interconnects 1332 are coupled to the plurality of interconnects 1312. Stage 7 also illustrates and describes a plurality of interconnects 1342 that are formed in at least the dielectric layer 204. The plurality of interconnects 1342 are coupled to the plurality of interconnects 1314. A plating process and a patterning process may be used to form the plurality of interconnects 1332 and/or the plurality of interconnects 1342.

Stage 8 of 13C, illustrates and describes an example of a state after a dielectric layer 205 and the dielectric layer 206 are formed. The dielectric layer 205 may include a plurality of cavities 1351. The dielectric layer 206 may include a plurality of cavities 1361. The dielectric layer 205 may be formed and coupled to a first surface (e.g., top surface) of the dielectric layer 203. The dielectric layer 206 may be formed and coupled to a second surface (e.g., bottom surface) of the dielectric layer 204. In some implementations, the dielectric layer 205 and/or the dielectric layer 206 may include a polymer. In some implementations, the dielectric layer 205 and/or the dielectric layer 206 may include Ajinomoto Build-up Film (ABF). In some implementations, the dielectric layer 205 and/or the dielectric layer 206 may include prepreg. The dielectric layer 205 and/or the dielectric layer 206 may be the same or different from the dielectric layer 203 and/or the dielectric layer 204.

The plurality of cavities 1351 are formed through a surface (e.g., first surface, top surface) of the dielectric layer 205. A laser process (e.g., laser ablation process) may be used to form the plurality of cavities 1351 in the dielectric layer 205. However, different implementations may use different processes to form the plurality of cavities 1351. The plurality of cavities 1361 are formed through a surface (e.g., second surface, bottom surface) of the dielectric layer 206. A laser process (e.g., laser ablation process) may be used to form the plurality of cavities 1361 in the dielectric layer 206. However, different implementations may use different processes to form the plurality of cavities 1361.

Stage 9 of FIG. 13D, illustrates and describes an example of a state after a plurality of interconnects 1352 that are formed in at least the dielectric layer 205. The plurality of interconnects 1352 are coupled to the plurality of interconnects 1332. Stage 9 also illustrates and describes a plurality of interconnects 1362 that are formed in at least the dielectric layer 206. The plurality of interconnects 1362 are coupled to the plurality of interconnects 1342. A plating process and a patterning process may be used to form the plurality of interconnects 1352 and/or the plurality of interconnects 1362.

The method forms (at 1430) at least one solder resist layer. Stage 10 of FIG. 13E, illustrates and describes an example of a state after a solder resist layer 207 is formed and patterned. The solder resist layer 207 may be coupled to the dielectric layer 1301. The dielectric layer 1301 may be at least one dielectric layer that represents all and/or part of the dielectric layer 201, the dielectric layer 203, the dielectric layer 205 and/or the dielectric layer 206. A deposition, a lamination, an exposure, a development and/or an etching process may be used to form and pattern the solder resist layer 207. The plurality of interconnects 1390 may be located at least in the dielectric layer 1301. The plurality of interconnects 1390 may represent all and/or part of the plurality of via interconnects 210, the plurality of interconnects 1312, the plurality of interconnects 1314, the plurality of interconnects 1332, the plurality of interconnects 1342, the plurality of interconnects 1352 and/or the plurality of interconnects 1362.

Stage 10 also illustrates and describes an example of a state after a solder resist layer 209 is formed and patterned. The solder resist layer 209 may be coupled to the dielectric layer 1301. A deposition, a lamination, an exposure, a development and/or an etching process may be used to form and pattern the solder resist layer 209.

The method couples (at 1435) a plurality of solder interconnects to interconnects of the substrate. In some implementations, a plurality of solder interconnects may be coupled to interconnects of the substrate 101 through openings in the solder resist layer 207 and/or openings in the solder resist layer 209.

Once the substrate (e.g., 101) is provided and/or fabricated, an integrated device (e.g., 103) may be coupled to the substrate through at least a plurality of bump interconnects (e.g., 130). The substrate and the integrated device may then be coupled to a board (e.g., 105) through a plurality of solder interconnects (e.g., 140).

Exemplary Sequence for Fabricating a Substrate with an Embedded Frame

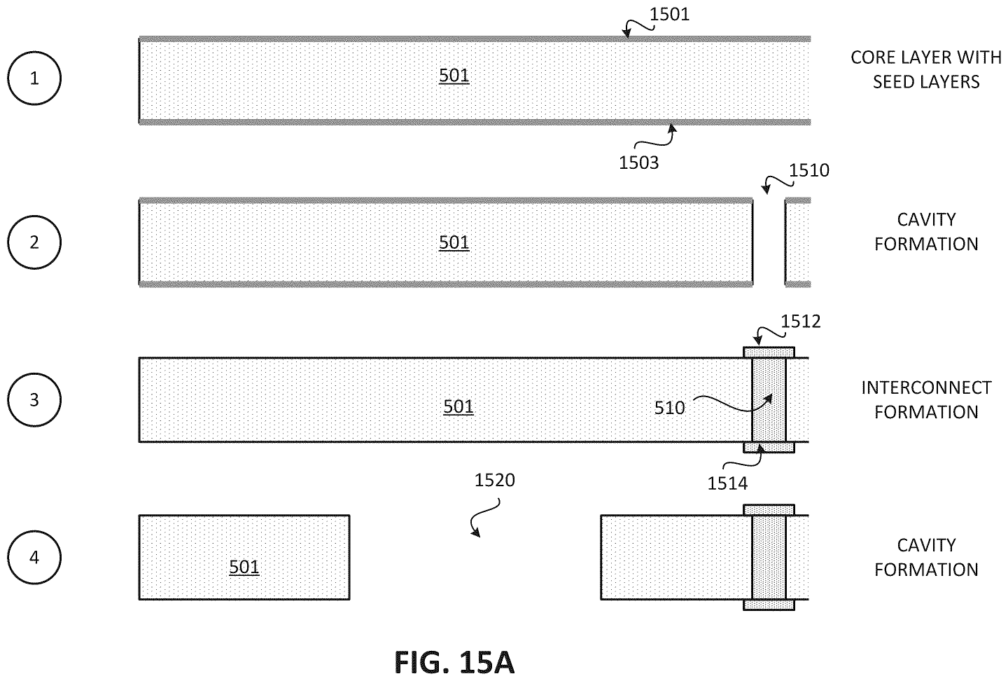

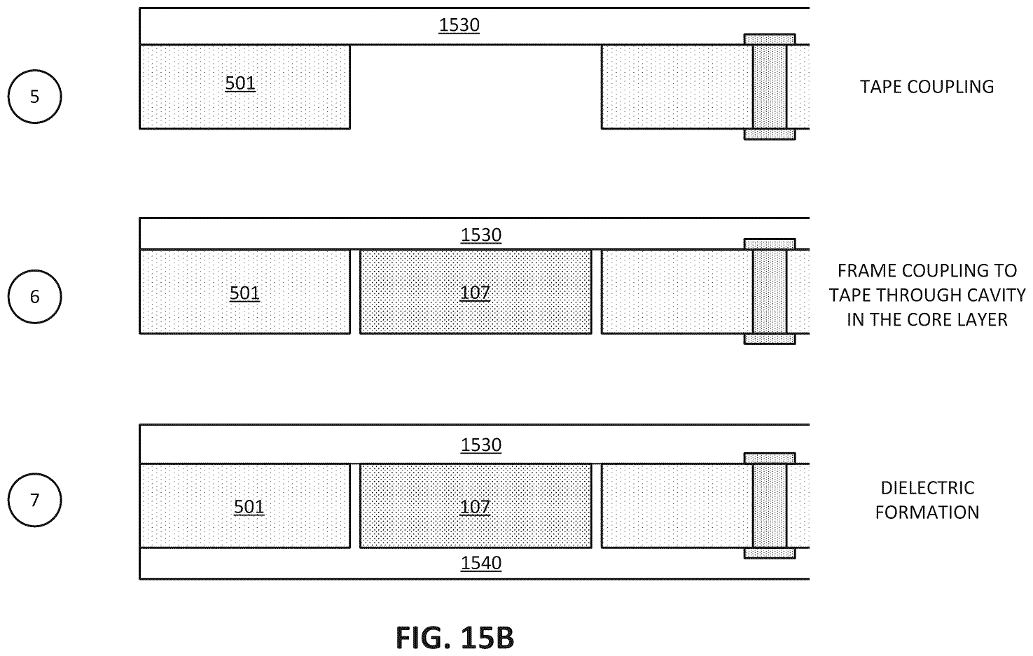

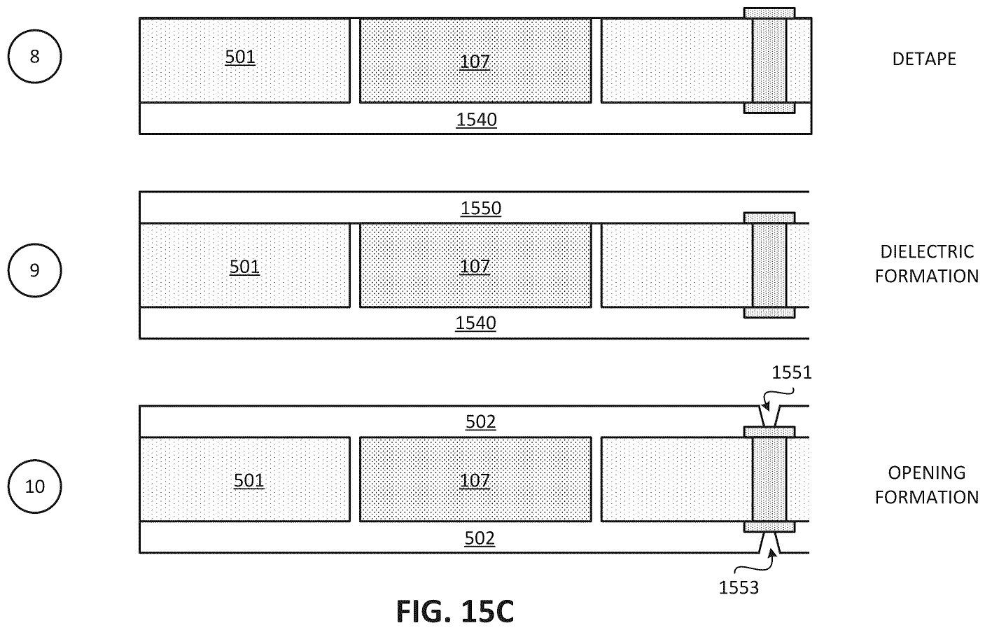

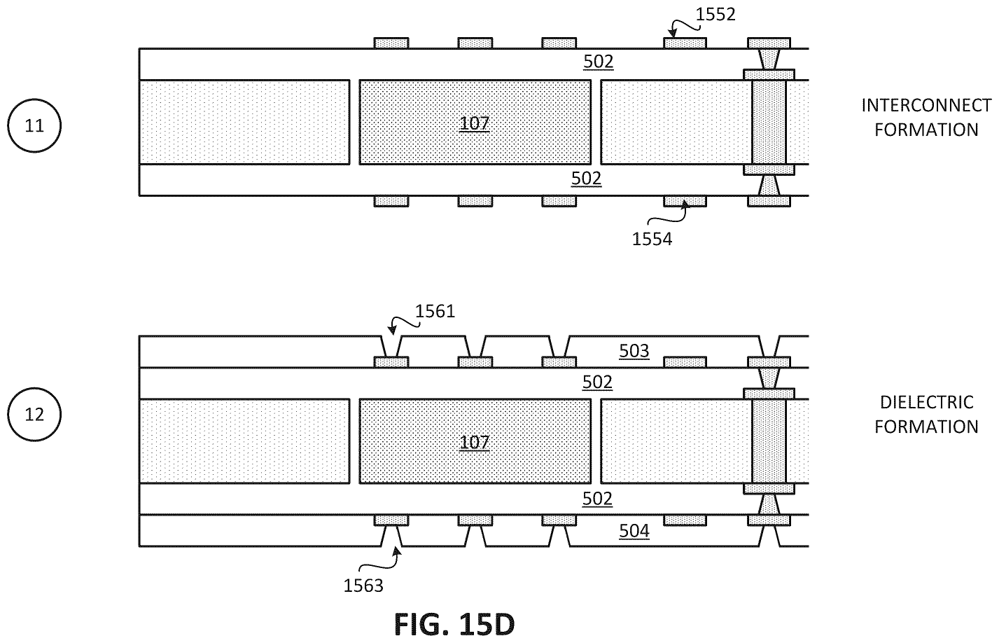

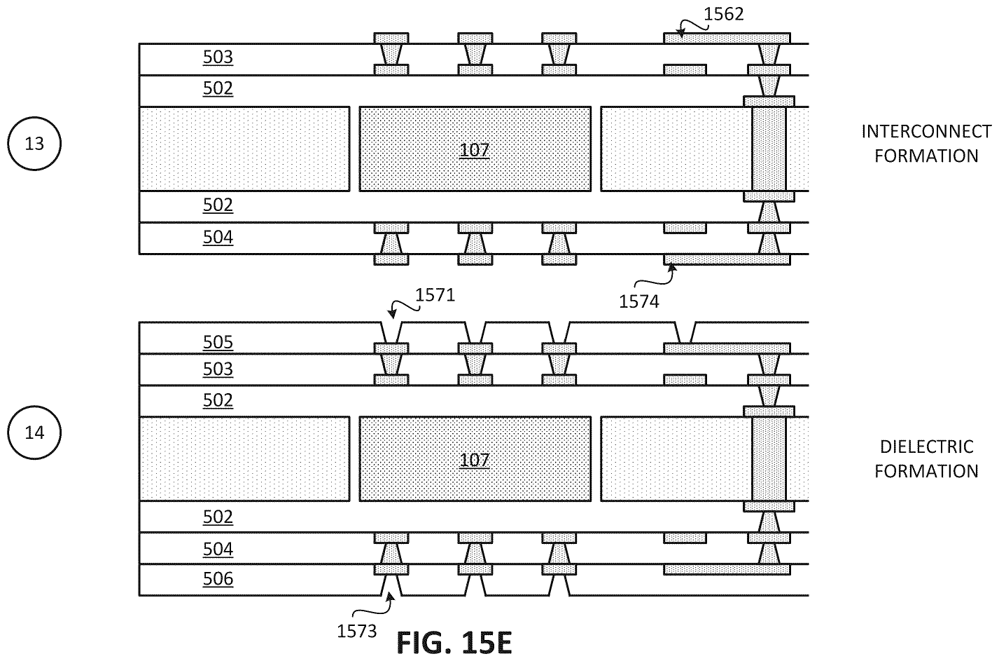

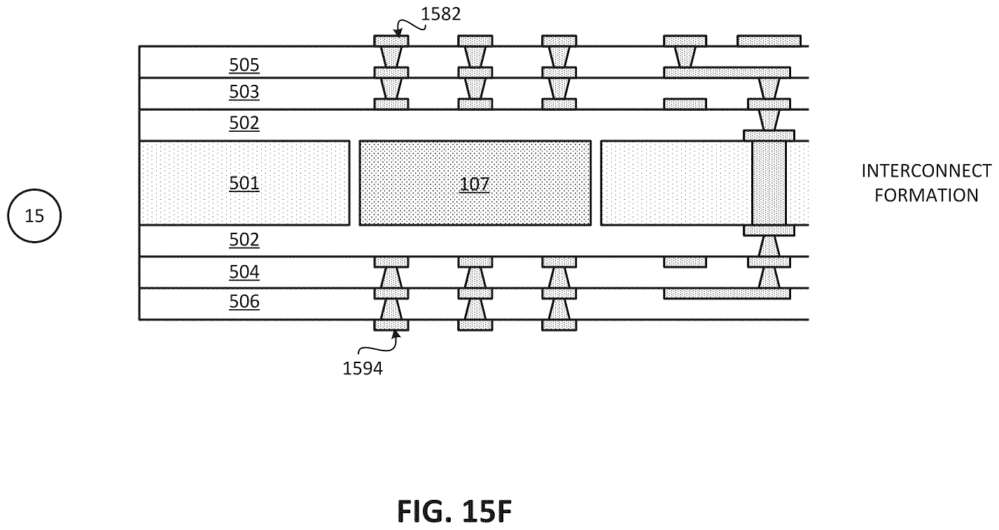

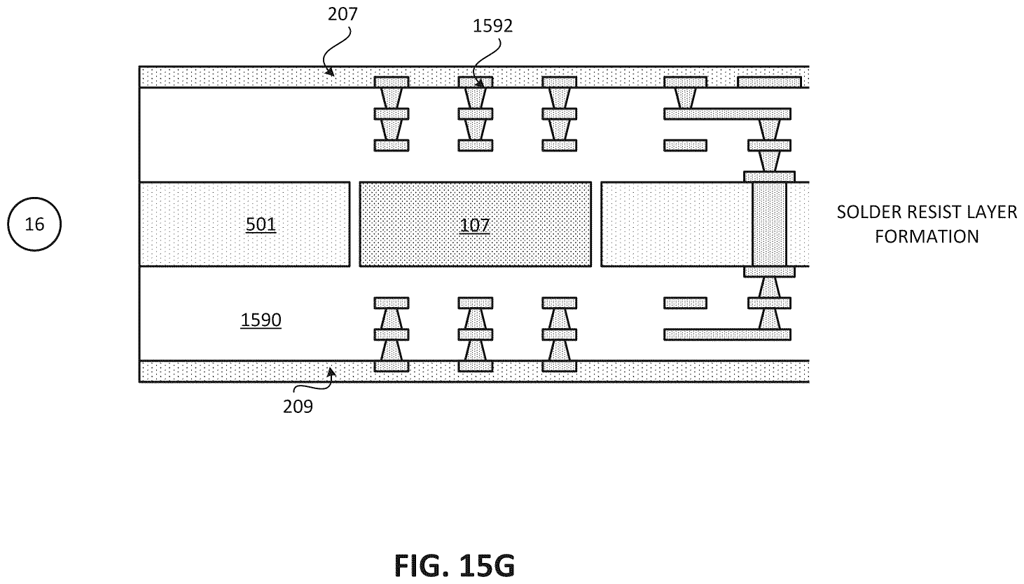

FIGS. 15A-15G illustrate an exemplary sequence for providing or fabricating a substrate with an embedded frame. In some implementations, the sequence of FIGS. 15A-15G may be used to provide or fabricate any of the substrates described in the disclosure. In some implementations, the sequence of FIGS. 15A-15G may be used to provide or fabricate the substrate 401 described in the disclosure.

It should be noted that the sequence of FIGS. 15A-15G may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 15A, illustrates a state after a core layer 501 is provided. The core layer 501 may include a seed layer 1501 coupled to a first surface of the core layer 501 and a seed layer 1503 coupled to a second surface of the core layer 501.

Stage 2 illustrates a state after a plurality of cavities 1510 are formed in the core layer 501. The plurality of cavities 1510 may be formed through the seed layer 1501 and the seed layer 1503. A laser process (e.g., laser ablation) may be used to form the plurality of cavities 1510. However, different implementations may use different processes to form the plurality of cavities 1510. The plurality of cavities 1500 may extend through the thickness of the core layer 501, the seed layer 1501 and/or the seed layer 1503.

Stage 3 illustrates a state after a plurality of via interconnects 510, a plurality of interconnects 1512 and a plurality of interconnects 1514. The plurality of via interconnects 510 may be formed in the plurality of cavities 1510. The plurality of interconnects 1512 may be formed and coupled to a first surface of the core layer 501. In some implementations, part of the seed layer 1501 may be part of the plurality of interconnects 1512. The plurality of interconnects 1512 may be coupled to the plurality of via interconnects 510. The plurality of interconnects 1514 may be formed and coupled to a second surface of the core layer 501. In some implementations, part of the seed layer 1503 may be part of the plurality of interconnects 1514. The plurality of interconnects 814 may be coupled to the plurality of via interconnects 510. A plating process and a patterning process may be used to form the plurality of via interconnects 510, the plurality of interconnects 1512 and/or the plurality of interconnects 1514.

Stage 4 illustrates a state after a cavity 1520 is formed in the core layer 501. The cavity 1520 may be formed through the core layer 501. A laser process (e.g., laser ablation) may be used to form the cavity 1520. However, different implementations may use different processes to form the cavity 1520. The cavity 1520 may extend through the thickness of the core layer 501.

Stage 5, as shown in FIG. 15B, illustrates a state after the core layer 501 with the cavity 1520 is coupled to a tape 1530. The tape 1530 may be a type of carrier. The tape 1530 may include an adhesive. The tape 1530 may be touching the plurality of interconnects 1512 and/or the core layer 501.

Stage 6 illustrates a state after an embedded frame 107, is coupled to the tape 1530. The embedded frame 107 is coupled to the tape 1530 through the cavity 1520 in the core layer 501. The embedded frame 107 is located at least partially in the cavity 1520 of the core layer 501.

Stage 7 illustrates a state after a dielectric layer 1540 is formed. The dielectric layer 1540 fills at least part of the cavity 1520 of the core layer 501. The dielectric layer 1540 is coupled to and touching the embedded frame 107 and the core layer 501. The dielectric layer 1540 may be coupled to a second surface (e.g., bottom surface) of the core layer 501. A deposition process and/or a lamination process may be used to form the dielectric layer 1540. In some implementations, the dielectric layer 1540 may include a polymer. In some implementations, the dielectric layer 1540 may include prepreg.

Stage 8, as shown in FIG. 15C, illustrates a state after the tape 1530 is decoupled from the core layer 501 and the embedded frame 107. The tape 1530 may be detached and/or peeled off.

Stage 9 illustrates a state after the dielectric layer 1550 is formed and coupled to the core layer 501 and the embedded frame 107. The dielectric layer 1550 may fill part of the cavity 1520 in the core layer 501 that is not occupied by the embedded frame 107 and/or the dielectric layer 1540. The dielectric layer 1550 may be coupled to the embedded frame 107 and a first surface (e.g., top surface) of the core layer 501. A deposition process and/or a lamination process may be used to form the dielectric layer 1550. In some implementations, the dielectric layer 1550 may include a polymer. In some implementations, the dielectric layer 1550 may include prepreg. The dielectric layer 1550 may be the same material as the dielectric layer 1540. The dielectric layer 1540 and the dielectric layer 1550 may be represented as the dielectric layer 502.

Stage 10 illustrates a state after a plurality of cavities 1551 are formed through a surface (e.g., first surface, top surface) of the dielectric layer 502. A laser process (e.g., laser ablation process) may be used to form the plurality of cavities 1551 in the dielectric layer 502. However, different implementations may use different processes to form the plurality of cavities 1551.

Stage 10 also illustrates a state after a plurality of cavities 1553 are formed through another surface (e.g., second surface, bottom surface) of the dielectric layer 502. A laser process (e.g., laser ablation process) may be used to form the plurality of cavities 1553 in the dielectric layer 502. However, different implementations may use different processes to form the plurality of cavities 1553.

Stage 11, as shown in FIG. 15D, illustrates a state after a plurality of interconnects 1552 and a plurality of interconnects 1554 are formed in at least the dielectric layer 502. A plating process and a patterning process may be used to form the plurality of interconnects 1552 and/or the plurality of interconnects 1554.

Stage 12 illustrates a state after a dielectric layer 503 and the dielectric layer 504 are formed. The dielectric layer 503 may include a plurality of cavities 1561. The dielectric layer 504 may include a plurality of cavities 1563. The dielectric layer 503 may be formed and coupled to a first surface (e.g., top surface) of the dielectric layer 502. The dielectric layer 504 may be formed and coupled to a second surface (e.g., bottom surface) of the dielectric layer 502. In some implementations, the dielectric layer 503 and/or the dielectric layer 504 may include a polymer. In some implementations, the dielectric layer 503 and/or the dielectric layer 504 may include Ajinomoto Build-up Film (ABF). In some implementations, the dielectric layer 503 and/or the dielectric layer 504 may include prepreg. The dielectric layer 503 and/or the dielectric layer 504 may be the same or different from the dielectric layer 502.

The plurality of cavities 1561 are formed through a surface (e.g., first surface, top surface) of the dielectric layer 503. A laser process (e.g., laser ablation process) may be used to form the plurality of cavities 1561 in the dielectric layer 503. However, different implementations may use different processes to form the plurality of cavities 1561. The plurality of cavities 1563 are formed through a surface (e.g., second surface, bottom surface) of the dielectric layer 504. A laser process (e.g., laser ablation process) may be used to form the plurality of cavities 1563 in the dielectric layer 504. However, different implementations may use different processes to form the plurality of cavities 1563.

Stage 13, as shown in FIG. 15E, illustrates a state after a plurality of interconnects 1562 that are formed in at least the dielectric layer 503. The plurality of interconnects 1562 are coupled to the plurality of interconnects 1552. Stage 13 also illustrates and describes a state after a plurality of interconnects 1574 that are formed in at least the dielectric layer 504. The plurality of interconnects 1574 are coupled to the plurality of interconnects 1554. A plating process and a patterning process may be used to form the plurality of interconnects 1562 and/or the plurality of interconnects 1574.

Stage 14 illustrates a state after a dielectric layer 505 and the dielectric layer 506 are formed. The dielectric layer 505 may include a plurality of cavities 1571. The dielectric layer 506 may include a plurality of cavities 1573. The dielectric layer 505 may be formed and coupled to a first surface (e.g., top surface) of the dielectric layer 503. The dielectric layer 506 may be formed and coupled to a second surface (e.g., bottom surface) of the dielectric layer 504. In some implementations, the dielectric layer 505 and/or the dielectric layer 506 may include a polymer. In some implementations, the dielectric layer 505 and/or the dielectric layer 506 may include Ajinomoto Build-up Film (ABF). In some implementations, the dielectric layer 505 and/or the dielectric layer 506 may include prepreg. The dielectric layer 505 and/or the dielectric layer 506 may be the same or different from the dielectric layer 502, the dielectric layer 503 and/or the dielectric layer 504.

The plurality of cavities 1571 are formed through a surface (e.g., first surface, top surface) of the dielectric layer 505. A laser process (e.g., laser ablation process) may be used to form the plurality of cavities 1571 in the dielectric layer 505. However, different implementations may use different processes to form the plurality of cavities 1571. The plurality of cavities 1573 are formed through a surface (e.g., second surface, bottom surface) of the dielectric layer 506. A laser process (e.g., laser ablation process) may be used to form the plurality of cavities 1573 in the dielectric layer 506. However, different implementations may use different processes to form the plurality of cavities 1573.

Stage 15, as shown in FIG. 15F, illustrates a state after a plurality of interconnects 1582 that are formed in at least the dielectric layer 505. The plurality of interconnects 1582 are coupled to the plurality of interconnects 1562. Stage 13 also illustrates and describes a state after a plurality of interconnects 1594 that are formed in at least the dielectric layer 506. The plurality of interconnects 1594 are coupled to the plurality of interconnects 1574. A plating process and a patterning process may be used to form the plurality of interconnects 1582 and/or the plurality of interconnects 1594.

Stage 16, as shown in FIG. 15G, illustrates a state after a solder resist layer 207 is formed and patterned. The solder resist layer 207 may be coupled to the dielectric layer 1590. The dielectric layer 1590 may be at least one dielectric layer that represents all and/or part of, the dielectric layer 502, a dielectric layer 503, the dielectric layer 504, the dielectric layer 505, and/or the dielectric layer 506. A deposition, a lamination, an exposure, a development and/or an etching process may be used to form and pattern the solder resist layer 207. The plurality of interconnects 1592 may be located at least in the dielectric layer 1590. The plurality of interconnects 1592 may represent all and/or part of the plurality of interconnects 1512, the plurality of interconnects 1514, the plurality of interconnects 1552, the plurality of interconnects 1554, the plurality of interconnects 1562, the plurality of interconnects 1574, the plurality of interconnects 1582 and/or the plurality of interconnects 1594. The dielectric layer 1590 may represent the at least one dielectric layer 420 and/or the at least one dielectric layer 430, as shown in at least FIG. 4. The plurality of interconnects 1592 may represent the plurality of interconnects 412, as shown in at least FIG. 4.

Stage 16 also illustrates and describes a state after a solder resist layer 209 is formed and patterned. The solder resist layer 209 may be coupled to the dielectric layer 1590. A deposition, a lamination, an exposure, a development and/or an etching process may be used to form and pattern the solder resist layer 209.

Exemplary Flow Diagram of a Method for Fabricating a Substrate with an Embedded Frame

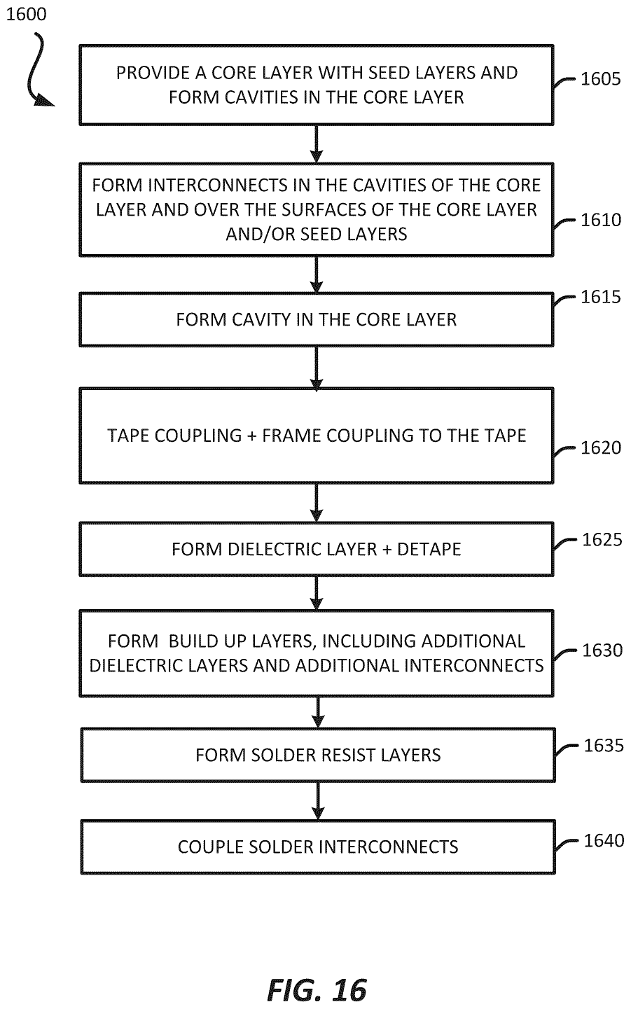

In some implementations, fabricating a substrate includes several processes. FIG. 16 illustrates an exemplary flow diagram of a method 1600 for providing or fabricating a substrate with an embedded frame. In some implementations, the method 1600 of FIG. 16 may be used to provide or fabricate the substrate 401.

It should be noted that the method 1600 of FIG. 16 may combine one or more processes in order to simplify and/or clarify the method for providing or fabricating a substrate. In some implementations, the order of the processes may be changed or modified.

The method provides (at 1605) a core layer with seed layers and forms cavities in the core layer. Stage 1 of FIG. 15A, illustrates and describes an example of a state after a core layer 501 is provided. The core layer 501 may include a seed layer 1501 coupled to a first surface of the core layer 501 and a seed layer 1503 coupled to a second surface of the core layer 501. Stage 2 of FIG. 15A, illustrates and describes an example of a state after a plurality of cavities 1510 are formed in the core layer 501. The plurality of cavities 1510 may be formed through the seed layer 1501 and the seed layer 1503. A laser process (e.g., laser ablation) may be used to form the plurality of cavities 1510. However, different implementations may use different processes to form the plurality of cavities 1510. The plurality of cavities 1500 may extend through the thickness of the core layer 501, the seed layer 1501 and/or the seed layer 1503.

The method forms (at 1610) interconnects in the cavities of the core layer and on surfaces of the core layer. Stage 3 of FIG. 15A, illustrates and describes an example of a state after a plurality of via interconnects 510, a plurality of interconnects 1512 and a plurality of interconnects 1514. The plurality of via interconnects 510 may be formed in the plurality of cavities 1510. The plurality of interconnects 1512 may be formed and coupled to a first surface of the core layer 501. In some implementations, part of the seed layer 1501 may be part of the plurality of interconnects 1512. The plurality of interconnects 1512 may be coupled to the plurality of via interconnects 510. The plurality of interconnects 1514 may be formed and coupled to a second surface of the core layer 501. In some implementations, part of the seed layer 1503 may be part of the plurality of interconnects 1514. The plurality of interconnects 814 may be coupled to the plurality of via interconnects 510. A plating process and a patterning process may be used to form the plurality of via interconnects 510, the plurality of interconnects 1512 and/or the plurality of interconnects 1514.

The method forms (at 1615) a cavity in the core layer. Stage 4 of FIG. 15A, illustrates and describes an example of a state after a cavity 1520 is formed in the core layer 501. The cavity 1520 may be formed through the core layer 501. A laser process (e.g., laser ablation) may be used to form the cavity 1520. However, different implementations may use different processes to form the cavity 1520. The cavity 1520 may extend through the thickness of the core layer 501.

The method couples (at 1620) the core layer to a tape and couples an embedded frame to the tape through the cavity in the core layer. Stage 5 of FIG. 15B, illustrates and describes an example of a state after the core layer 501 with the cavity 1520 is coupled to a tape 1530. The tape 1530 may be a type of carrier. The tape 1530 may include an adhesive. The tape 1530 may be touching the plurality of interconnects 1512 and/or the core layer 501.

Stage 6 of FIG. 15B, illustrates and describes an example of a state after an embedded frame 107, is coupled to the tape 1530. The embedded frame 107 is coupled to the tape 1530 through the cavity 1520 in the core layer 501. The embedded frame 107 is located at least partially in the cavity 1520 of the core layer 501.

The method forms (at 1625) a dielectric layer and detapes. Stage 7 of FIG. 15B, illustrates and describes an example of a state after a dielectric layer 1540 is formed. The dielectric layer 840 fills at least part of the cavity 1520 of the core layer 501. The dielectric layer 1540 is coupled to the embedded frame 107 and the core layer 501. The dielectric layer 1540 may be coupled to a second surface (e.g., bottom surface) of the core layer 501. A deposition process and/or a lamination process may be used to form the dielectric layer 1540. In some implementations, the dielectric layer 1540 may include a polymer. In some implementations, the dielectric layer 1540 may include prepreg.

Stage 8 of FIG. 15C, illustrates and describes an example of a state after the tape 1530 is decoupled from the core layer 501 and the embedded frame 107. The tape 1530 may be detached and/or peeled off.

The method forms (at 1630) at least one build up layer, which includes at least one dielectric layer and a plurality of interconnects. Stage 9 of FIG. 15C through stage 15 of FIG. 15F, illustrate and describes an example of forming build up layers for the substrate.

Stage 9 of FIG. 15C, illustrates and describes an example of a state after the dielectric layer 1550 is formed and coupled to the core layer 501 and the embedded frame 107. The dielectric layer 1550 may fill part of the cavity 1520. The dielectric layer 1550 may be coupled to the embedded frame 107 and a first surface (e.g., top surface) of the core layer. A deposition process and/or a lamination process may be used to form the dielectric layer 1550. In some implementations, the dielectric layer 1550 may include a polymer. In some implementations, the dielectric layer 1550 may include prepreg. The dielectric layer 1550 may be the same material as the dielectric layer 1540. The dielectric layer 1540 and the dielectric layer 1550 may be represented as the dielectric layer 502.

Stage 10 of FIG. 15C, illustrates and describes an example of a state after a plurality of cavities 1551 are formed through a surface (e.g., first surface, top surface) of the dielectric layer 502. A laser process (e.g., laser ablation process) may be used to form the plurality of cavities 1551 in the dielectric layer 502. However, different implementations may use different processes to form the plurality of cavities 1551.

Stage 10 also illustrates and describes an example of a state after a plurality of cavities 1553 are formed through another surface (e.g., second surface, bottom surface) of the dielectric layer 502. A laser process (e.g., laser ablation process) may be used to form the plurality of cavities 1553 in the dielectric layer 502. However, different implementations may use different processes to form the plurality of cavities 1553.

Stage 11 of FIG. 15D, illustrates and describes an example of a state after a plurality of interconnects 1552 and a plurality of interconnects 1554 are formed in at least the dielectric layer 502. A plating process and a patterning process may be used to form the plurality of interconnects 1552 and/or the plurality of interconnects 1554.

Stage 12 of FIG. 15D, illustrates and describes an example of a state after a dielectric layer 503 and the dielectric layer 504 are formed. The dielectric layer 503 may include a plurality of cavities 1561. The dielectric layer 504 may include a plurality of cavities 1563. The dielectric layer 503 may be formed and coupled to a first surface (e.g., top surface) of the dielectric layer 502. The dielectric layer 504 may be formed and coupled to a second surface (e.g., bottom surface) of the dielectric layer 502. In some implementations, the dielectric layer 503 and/or the dielectric layer 504 may include a polymer. In some implementations, the dielectric layer 503 and/or the dielectric layer 504 may include Ajinomoto Build-up Film (ABF). In some implementations, the dielectric layer 503 and/or the dielectric layer 504 may include prepreg. The dielectric layer 503 and/or the dielectric layer 504 may be the same or different from the dielectric layer 502.

The plurality of cavities 1561 are formed through a surface (e.g., first surface, top surface) of the dielectric layer 503. A laser process (e.g., laser ablation process) may be used to form the plurality of cavities 1561 in the dielectric layer 503. However, different implementations may use different processes to form the plurality of cavities 1561. The plurality of cavities 1563 are formed through a surface (e.g., second surface, bottom surface) of the dielectric layer 504. A laser process (e.g., laser ablation process) may be used to form the plurality of cavities 1563 in the dielectric layer 504. However, different implementations may use different processes to form the plurality of cavities 1563.

Stage 13 of FIG. 15E, illustrates and describes an example of a state after a plurality of interconnects 1562 that are formed in at least the dielectric layer 503. The plurality of interconnects 1562 are coupled to the plurality of interconnects 1552. Stage 13 also illustrates and describes a plurality of interconnects 1574 that are formed in at least the dielectric layer 504. The plurality of interconnects 1574 are coupled to the plurality of interconnects 1554. A plating process and a patterning process may be used to form the plurality of interconnects 1562 and/or the plurality of interconnects 1574.

Stage 14 of FIG. 15E, illustrates and describes an example of a state after a dielectric layer 505 and the dielectric layer 506 are formed. The dielectric layer 505 may include a plurality of cavities 1571. The dielectric layer 506 may include a plurality of cavities 1573. The dielectric layer 505 may be formed and coupled to a first surface (e.g., top surface) of the dielectric layer 503. The dielectric layer 506 may be formed and coupled to a second surface (e.g., bottom surface) of the dielectric layer 504. In some implementations, the dielectric layer 505 and/or the dielectric layer 506 may include a polymer. In some implementations, the dielectric layer 505 and/or the dielectric layer 506 may include Ajinomoto Build-up Film (ABF). In some implementations, the dielectric layer 505 and/or the dielectric layer 506 may include prepreg. The dielectric layer 505 and/or the dielectric layer 506 may be the same or different from the dielectric layer 502, the dielectric layer 503 and/or the dielectric layer 504.

The plurality of cavities 1571 are formed through a surface (e.g., first surface, top surface) of the dielectric layer 505. A laser process (e.g., laser ablation process) may be used to form the plurality of cavities 1571 in the dielectric layer 505. However, different implementations may use different processes to form the plurality of cavities 1571. The plurality of cavities 1573 are formed through a surface (e.g., second surface, bottom surface) of the dielectric layer 506. A laser process (e.g., laser ablation process) may be used to form the plurality of cavities 1573 in the dielectric layer 506. However, different implementations may use different processes to form the plurality of cavities 1573.

Stage 15 of FIG. 15F, illustrates and describes an example of a state after a plurality of interconnects 1582 that are formed in at least the dielectric layer 505. The plurality of interconnects 1582 are coupled to the plurality of interconnects 1562. Stage 13 also illustrates and describes a plurality of interconnects 1594 that are formed in at least the dielectric layer 506. The plurality of interconnects 1594 are coupled to the plurality of interconnects 1574. A plating process and a patterning process may be used to form the plurality of interconnects 1582 and/or the plurality of interconnects 1594.

The method forms (at 1635) at least one solder resist layer. Stage 16 of FIG. 15G, illustrates and describes an example of a state after a solder resist layer 207 is formed and patterned. The solder resist layer 207 may be coupled to the dielectric layer 1590. The dielectric layer 1590 may be at least one dielectric layer that represents all and/or part of, the dielectric layer 502, a dielectric layer 503, the dielectric layer 504, the dielectric layer 505, and/or the dielectric layer 506. A deposition, a lamination, an exposure, a development and/or an etching process may be used to form and pattern the solder resist layer 207. The plurality of interconnects 1592 may be located at least in the dielectric layer 1590. The plurality of interconnects 1592 may represent all and/or part of the plurality of interconnects 1512, the plurality of interconnects 1514, the plurality of interconnects 1552, the plurality of interconnects 1554, the plurality of interconnects 1562, the plurality of interconnects 1574, the plurality of interconnects 1582 and/or the plurality of interconnects 1594.

Stage 16 also illustrates and describes an example of a state after a solder resist layer 209 is formed and patterned. The solder resist layer 209 may be coupled to the dielectric layer 1590. A deposition, a lamination, an exposure, a development and/or an etching process may be used to form and pattern the solder resist layer 209.

The method couples (at 1640) a plurality of solder interconnects to interconnects of the substrate. In some implementations, a plurality of solder interconnects may be coupled to interconnects of the substrate 401 through openings in the solder resist layer 207 and/or openings in the solder resist layer 209.

Once the substrate (e.g., 401) is provided and/or fabricated, an integrated device (e.g., 103) may be coupled to the substrate through at least a plurality of bump interconnects (e.g., 130). The substrate and the integrated device may then be coupled to a board (e.g., 105) through a plurality of solder interconnects (e.g., 140).

Exemplary Sequence for Fabricating a Substrate with an Embedded Frame

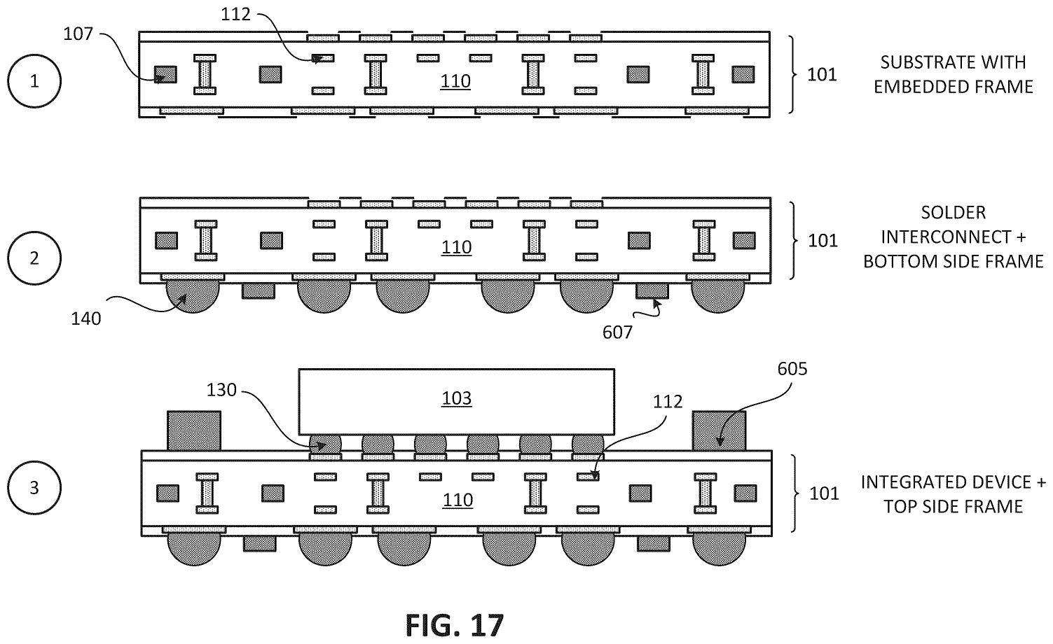

FIG. 17 illustrate an exemplary sequence for providing or fabricating a package comprising a substrate with an embedded frame. In some implementations, the sequence of FIG. 17 may be used to provide or fabricate any of the packages described in the disclosure. In some implementations, the sequence of FIG. 17 may be used to provide or fabricate the package 600 described in the disclosure.

It should be noted that the sequence of FIG. 17 may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 17, illustrates a state after a substrate 101 is provided. The substrate 101 includes an embedded frame 107. The substrate 101 may be fabricated using the fabrication process described in at least FIGS. 13A-13E of the disclosure. In some implementations, instead of the substrate 101, the substrate 401 may be provided. The substrate 401 may be fabricated using the fabrication process described in at least FIGS. 15A-15G of the disclosure.

Stage 2 illustrates a state after the plurality of solder interconnects 140 and a frame 607 are coupled to the substrate 101. A solder reflow process may be used to couple the plurality of solder interconnects 140 to the substrate. An adhesive or a solder may be used to couple the frame 607 to the substrate 101. The plurality of solder interconnects 140 and the frame 607 may be coupled to a bottom side and/or a bottom surface of the substrate 101. The bottom surface of the substrate 101 may be a landside surface of the substrate 101.

Stage 3 illustrates a state after the integrated device 103 is coupled to the substrate 101 through at least a plurality of bump interconnects 130. A plurality of bump interconnects 130 may include a plurality of pillar interconnects and/or a plurality of solder interconnects. A solder reflow process may be used to couple the integrated device 103 to the substrate 101. Stage 3 also illustrates a frame 605 that is coupled to a surface of the substrate 101. An adhesive or a solder may be used to couple the frame 605 to the substrate 101. The plurality of bump interconnects 130 and the frame 605 may be coupled to a top side and/or a top surface of the substrate 101. The top surface of the substrate 101 may be a die side surface of the substrate 101. Stage 3 may illustrate an example of the package 600 that includes a substrate 101, an embedded frame 107, a frame 605 and a frame 607. The embedded frame 107, the frame 605 and/or the frame 607 are configured as stiffeners to help strengthen the substrate 101 and/or the package 600.

### Exemplary Embedded Frame Designs

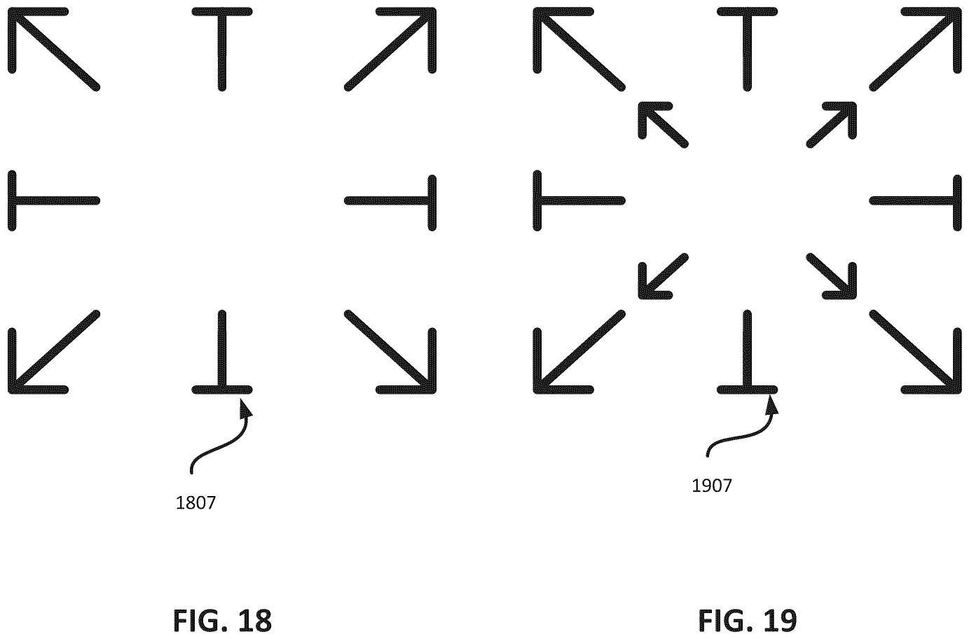

FIGS. 18 and 19 illustrate exemplary designs of different embedded frames that may be implemented in a substrate. FIG. 18 illustrates an embedded frame 1807, and FIG. 19 illustrates an embedded frame 1907. The designs of the embedded frame 1807, the embedded frame 1907 and/or the embedded frame 107 may be designed to consider the different routing of interconnects that a substrate may have. The design of the embedded frame 1807 and/or the embedded frame 1907 include several separate portions. However, it is noted that the embedded frame 1807 and/or the embedded frame 1907 may be formed as one continuous and/or contiguous frame. The embedded frame 1807 and/or the embedded frame 1907 may have a uniform thickness or may have different thicknesses for different portions and/or parts of the embedded frame. The shape of the embedded frames may be symmetrical or asymmetrical.

### Exemplary Electronic Devices

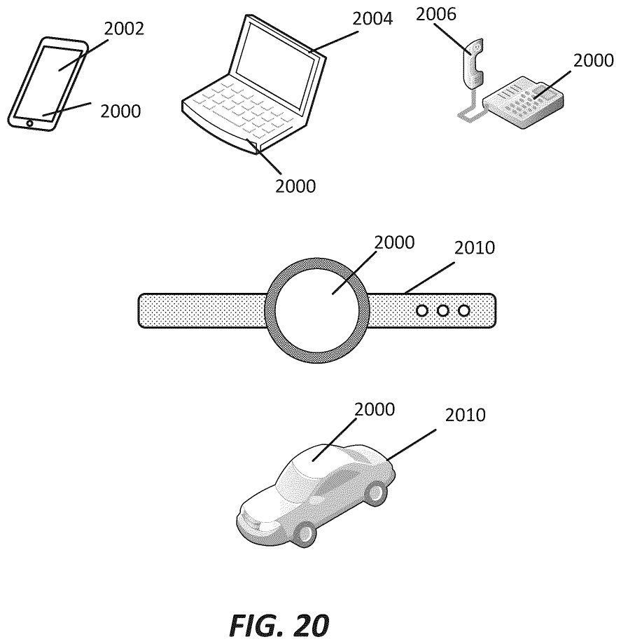

FIG. 20 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 2002, a laptop computer device 2004, a fixed location terminal device 2006, a wearable device 2008, or automotive vehicle 2010 may include a device 2000 as described herein. The device 2000 may be, for example, any of the devices and/or integrated circuit (IC) packages described herein. The devices 2002, 2004, 2006 and 2008 and the vehicle 2010 illustrated in FIG. 20 are merely exemplary. Other electronic devices may also feature the device 2000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-12, 13A-13E, 14, 15A-15G and/or 16-20 may be rearranged and/or combined into a single component, process, feature or function or embodied in several components, processes, or functions. Additional elements, components, processes, and/or functions may also be added without departing from the disclosure. It should also be noted FIGS. 1-12, 13A-13E, 14, 15A-15G and/or 16-20 and its corresponding description in the present disclosure is not limited to dies and/or ICs. In some implementations, FIGS. 1-12, 13A-13E, 14, 15A-15G and/or 16-20 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising an integrated device; and a substrate coupled to the integrated device through at least a plurality of solder interconnects. The substrate comprises at least one dielectric layer; a frame at least partially located in the at least one dielectric layer; and a plurality of interconnects located at least partially in the at least one dielectric layer.

Aspect 2: The package of aspect 1, wherein the substrate includes a core layer, wherein the frame is surrounded at least partially by the core layer.

Aspect 3: The package of aspect 2, wherein the frame touches the at least one dielectric layer.

Aspect 4: The package of aspects 2 through 3, wherein the core layer includes a cavity, and wherein the frame is located at least partially in the cavity of the core layer.

Aspect 5: The package of aspect 4, wherein at least part of the cavity of the core layer is occupied by the at least one dielectric layer.

Aspect 6: The package of aspects 1 through 5, wherein at least part of the frame is located along a periphery of the substrate.

Aspect 7: The package of aspects 1 through 6, wherein the frame includes a different material from the plurality of interconnects.

Aspect 8: The package of aspects 1 through 7, wherein the frame is an embedded frame, and wherein the package further comprises a second frame coupled to a surface of the substrate.

Aspect 9: The package of aspect 8, wherein the surface of the substrate is a landside surface of the substrate.

Aspect 10: The package of aspects 8 through 9, further comprising a second frame coupled to another surface of the substrate.

Aspect 11: A package comprising an integrated device; a substrate coupled to the integrated device through at least a first plurality of solder interconnects, wherein the integrated device is coupled to a first surface of the substrate. The substrate comprises at least one dielectric layer; and a plurality of interconnects located at least partially in the at least one dielectric layer; a second plurality of solder interconnects coupled to a second surface of the substrate; and a first frame coupled to the second surface of the substrate.

Aspect 12: The package of aspect 11, further comprising a second frame coupled to the first surface of the substrate.

Aspect 13: The package of aspects 11 through 12, wherein the substrate includes a core layer.

Aspect 14: The package of aspects 11 through 13, wherein the substrate includes an embedded frame located in the substrate.

Aspect 15: The package of aspect 14, wherein the embedded frame touches the at least one dielectric layer.

Aspect 16: A substrate comprising at least one dielectric layer; a first frame at least partially located in the at least one dielectric layer; and a plurality of interconnects located at least partially in the at least one dielectric layer.

Aspect 17: The substrate of aspect 16, wherein the substrate includes a core layer, wherein the first frame is surrounded at least partially by the core layer.

Aspect 18: The substrate of aspect 17, wherein the first frame touches the at least one dielectric layer.

Aspect 19: The substrate of aspects 17 through 18, wherein the core layer includes a cavity, and wherein the first frame is located at least partially in the cavity of the core layer.

Aspect 20: The substrate of aspect 19, wherein at least part of the cavity of the core layer is occupied by the at least one dielectric layer.

Aspect 21: A method for fabricating a package. The method provides a substrate comprising: at least one dielectric layer; a frame at least partially located in the at least one dielectric layer; and a plurality of interconnects located at least partially in the at least one dielectric layer. The method couples an integrated device to the substrate through at least a plurality of solder interconnects.

Aspect 22: The method of aspect 21, wherein the substrate includes a core layer, wherein the frame is surrounded at least partially by the core layer.

Aspect 23: The method of aspect 22, wherein the frame touches the at least one dielectric layer.

Aspect 24: The method of aspects 22 through 23, wherein the core layer includes a cavity, and wherein the frame is located at least partially in the cavity of the core layer.

Aspect 25: The method of aspect 24, wherein at least part of the cavity of the core layer is occupied by the at least one dielectric layer.

Aspect 26: The method of aspects 21 through 25, wherein at least part of the frame is located along a periphery of the substrate.

Aspect 27: The method of aspects 21 through 26, wherein the frame includes a different material from the plurality of interconnects.

Aspect 28: The method of aspects 21 through 27, wherein the frame is an embedded frame, and wherein the method further comprises coupling a second frame to a surface of the substrate.

Aspect 29: The method of aspect 28, wherein the surface of the substrate is a landside surface of the substrate.

Aspect 30: The method of aspects 28 through 29, further comprising coupling a third frame to another surface of the substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
an integrated device; and
a substrate coupled to the integrated device through at least a plurality of solder interconnects, the substrate comprising:
at least one dielectric layer;
a frame at least partially located in the at least one dielectric layer; and
a plurality of interconnects located at least partially in the at least one dielectric layer.

2. The package of claim 1, wherein the substrate includes a core layer, wherein the frame is surrounded at least partially by the core layer.

3. The package of claim 2, wherein the frame touches the at least one dielectric layer.

4. The package of claim 2,
wherein the core layer includes a cavity, and
wherein the frame is located at least partially in the cavity of the core layer.

5. The package of claim 4, wherein at least part of the cavity of the core layer is occupied by the at least one dielectric layer.

6. The package of claim 1, wherein at least part of the frame is located along a periphery of the substrate.

7. The package of claim 1, wherein the frame includes a different material from the plurality of interconnects.

8. The package of claim 1,
wherein the frame is an embedded frame, and
wherein the package further comprises a second frame coupled to a surface of the substrate.

9. The package of claim 8, wherein the surface of the substrate is a landside surface of the substrate.

10. The package of claim 8, further comprising a second frame coupled to another surface of the substrate.

11. A package comprising:
an integrated device;
a substrate coupled to the integrated device through at least a first plurality of solder interconnects, wherein the integrated device is coupled to a first surface of the substrate, the substrate comprising:
at least one dielectric layer; and
a plurality of interconnects located at least partially in the at least one dielectric layer;
a second plurality of solder interconnects coupled to a second surface of the substrate; and
a first frame coupled to the second surface of the substrate.

12. The package of claim 11, further comprising a second frame coupled to the first surface of the substrate.

13. The package of claim 11, wherein the substrate includes a core layer.

14. The package of claim 11, wherein the substrate includes an embedded frame located in the substrate.

15. The package of claim 14, wherein the embedded frame touches the at least one dielectric layer.

16. A substrate comprising:
at least one dielectric layer;
a first frame at least partially located in the at least one dielectric layer; and
a plurality of interconnects located at least partially in the at least one dielectric layer.

17. The substrate of claim 16, wherein the substrate includes a core layer, wherein the first frame is surrounded at least partially by the core layer.

18. The substrate of claim 17, wherein the first frame touches the at least one dielectric layer.

19. The substrate of claim 17,
wherein the core layer includes a cavity, and
wherein the first frame is located at least partially in the cavity of the core layer.

20. The substrate of claim 19, wherein at least part of the cavity of the core layer is occupied by the at least one dielectric layer.

21. A method for fabricating a package, comprising:
providing a substrate comprising:
at least one dielectric layer;
a frame at least partially located in the at least one dielectric layer; and
a plurality of interconnects located at least partially in the at least one dielectric layer; and
coupling an integrated device to the substrate through at least a plurality of solder interconnects.

22. The method of claim 21, wherein the substrate includes a core layer, wherein the frame is surrounded at least partially by the core layer.

23. The method of claim 22, wherein the frame touches the at least one dielectric layer.

24. The method of claim 22,
wherein the core layer includes a cavity, and
wherein the frame is located at least partially in the cavity of the core layer.

25. The method of claim 24, wherein at least part of the cavity of the core layer is occupied by the at least one dielectric layer.

26. The method of claim 21, wherein at least part of the frame is located along a periphery of the substrate.

27. The method of claim 21, wherein the frame includes a different material from the plurality of interconnects.

28. The method of claim 21,
wherein the frame is an embedded frame, and
wherein the method further comprises coupling a second frame to a surface of the substrate.

29. The method of claim 28, wherein the surface of the substrate is a landside surface of the substrate.

30. The method of claim 28, further comprising coupling a third frame to another surface of the substrate.
